(19) United States
(12) Patent Application Publication
(10) Pub. No.: US 2016/0141530 A1
(43) Pub. Date: May 19, 2016

(54) SEMICONDUCTOR ELEMENT AND SEMICONDUCTOR ELEMENT MANUFACTURING METHOD

(71) Applicant: SHARP KABUSHIKI KAISHA, Osaka (JP)

(72) Inventor: Katsuyuki SUGA, Osaka (JP)

(73) Assignee: Sharp Kabushiki Kaisha, Osaka (JP)

(21) Appl. No.: 14/897,530

(22) PCT Filed: Feb. 28, 2014
(86) PCT No.: PCT/JP2014/055029

§ 371 Date: Dec. 10, 2015

(30) Foreign Application Priority Data
Jun. 11, 2013 (JP) 2013-122789

(51) Int. Cl. H01L 51/05; H01L 51/00; H01L 51/10

(52) U.S. Cl. CPC H01L 51/0545; H01L 51/0529; H01L 51/105; H01L 51/0021; H01L 51/055

(57) ABSTRACT

In an organic TFT (1), a material used for uppermost layers (14b, 15b) of a source electrode (14) and a drain electrode (15) has a smaller difference in work function relative to a material used for a semiconductor layer (16) than does a material used for layers of the source electrode (14) and the drain electrode (15) other than the uppermost layers (14a, 14b). The top surfaces and side faces of the uppermost layers of the source electrode (14) and the drain electrode (15) contact the semiconductor layer (16) directly, and the layers of the source electrode (14) and the drain electrode (15) other than the uppermost layers are separated from the semiconductor layer (16) by a second gate insulating layer (12).

### TECHNICAL FIELD

The present invention relates to a semiconductor element and a method for manufacturing a semiconductor element.

### BACKGROUND ART

In recent years, thin film transistors (TFTs) that employ organic semiconductor layers have attracted attention as next-generation transistor technology.

Organic TFTs can be manufactured using relatively low temperature-processes at temperatures on the order of 100° C. to 200° C. and can therefore be formed directly on top of a plastic substrate. Moreover, organic TFTs exhibit excellent durability to bending because both the semiconductor layer and the insulating layers are formed using organic materials. Organic TFTs are therefore expected to have wide applications in flexible display technologies such as liquid crystal film and e-paper.

One typical, widely used structure for organic TFTs is the bottom-gate, bottom-contact structure. In the bottom-gate, bottom-contact structure, the gate electrode and the gate insulating layer are formed on a substrate, and then the source electrode and the drain electrode are formed on top of the gate insulating layer. Then, the organic semiconductor is formed on top of the gate insulating layer, the source electrode, and the drain electrode.

During the research and development stage of organic TFT technologies, a metal such as gold that makes good contact with the organic semiconductor layer is used as the material for the source electrode and the drain electrode, which are typically formed as single-layer gold (Au) films.

In bottom-gate organic TFTs, a channel is formed in the organic semiconductor between the source electrode and the drain electrode in the region near the interface between the organic semiconductor layer and the gate insulating layer, and current flows through the organic semiconductor via this channel.

Patent Document 1 discloses an organic transistor structure and a method for manufacturing the same in which the mobility of the carriers that move through the channel in the organic semiconductor is improved by also forming the gate insulating layer between the source electrode and the drain electrode as a planarizing layer that planarizes the organic semiconductor layer.

Moreover, Non-Patent Document 1 discloses a configuration for a bottom-gate organic transistor in which additional adhesion layers are formed. Here, “adhesion layers” refers to auxiliary metal layers formed in the gate electrode, the source electrode, and the drain electrode in order to improve adhesion between each electrode and the underlying material (the substrate or the gate insulating layer).

### RELATED ART DOCUMENTS

### Patent Documents

Patent Document 1: Japanese Patent Application Laid-Open Publication, “Japanese Patent Application Laid-Open Publication No. 2007-266355 (Published on Oct. 11, 2007)”

### Non-Patent Documents

Non-Patent Document 1: Sang Mi Cho, Seung Hoon Han, Jun Hee Kim, and Jin Jang, “Photoleakage currents in organic thin-film transistors,” Applied Physics Letters Vol. 88 071106, 2006.

Non-Patent Document 2: Yu Kimura, Fumio Mochizuki, Takashi Nagase, Takashi Kobayashi, Kazuo Takimiya, Masaaki Ikeda, and Hiroyoshi Naito, “Device Performance of Benzothienobenzothiophene-Based Top-Gate Organic Field-Effect Transistors with Embedded Electrodes”, IDW2012 Proceedings, AMDp2-1, 2012.

Non-Patent Document 3: J. Veres, S. D. Ogier, S. W. Leeming, D. C. Cupertino, and S. Mohialdin Khaffaf, “Low-k Insulators as the Choice of Dielectrics in Organic Field-Effect Transistors”, Advanced Functional Materials, Vol. 13, No. 3, pp. 199-204, 2003.

Non-Patent Document 4: Tokiyoshi Umeda, Daisuke Kumaki, and Shizuo Tokitol, “Surface-energy-dependent field-effect mobilities up to 1 cm2/V s for polymer thin-film transistor”, Journal of Applied Physics, Vol. 105, Issue 2, DEVICE PHYSICS, 2009.

### SUMMARY OF THE INVENTION

### Problems to be Solved by the Invention

However, the conventional technologies disclosed in Patent Documents 1 and 2 exhibit the following problems.

As disclosed in Patent Document 2, during production, in bottom-gate organic TFTs the source electrode and the drain electrode each include multiple layers. In other words, in the gate electrode, the source electrode, and the drain electrode, a metal layer made from a metal such as titanium (Ti) or chromium (Cr) is formed as a first layer (adhesion layer) beneath a second layer (contact layer) made from a material such as gold (Au) in order to improve adhesion between each electrode and the underlying material (the substrate or the gate insulating layer).

However, the first layer made from Ti or the like cannot make good contact with the organic semiconductor layer, and therefore the presence of this adhesion layer increases the contact resistance with the organic semiconductor. As a result, the current that flows through the organic semiconductor channel decreases in magnitude, thereby decreasing the performance of the organic TFT.

In the organic transistor disclosed in Patent Document 1, however, the source electrode and the drain electrode are formed as single-layer metal films, and therefore the organic transistor structure disclosed in Patent Document 1 is the same as the bottom-gate organic TFT structure typically used during the research and development stage.

Therefore, the conventional technologies disclosed in Patent Documents 1 and 2 cannot address the decreases in performance that occur when using multilayer source and drain electrodes in a semiconductor element.

The present invention was made to solve the abovementioned problems and aims to provide a semiconductor element and method for manufacturing the same that can reduce the performance decreases that typically occur when using multilayer source and drain electrodes in a semiconductor element.

### Means for Solving the Problems

To solve the above-mentioned problems, in one aspect of the present invention, a semiconductor element of the present invention includes: a gate electrode; a first gate insulating layer covering the gate electrode; a source electrode and a drain electrode formed with a gap therebetween on the first gate insulating layer such that, in a plan view, the source electrode and the drain electrode are disposed on respective sides of the gate electrode and both partially overlap the gate electrode through the first gate insulating layer; a second gate insulating layer formed on the first gate insulating layer in at least a region between the source electrode and the drain electrode; and a semiconductor layer formed between and on top of the source electrode and the drain electrode, the semiconductor layer overlapping the gate electrode through the first gate insulating layer, the second gate insulating layer, the source electrode, and the drain electrode, wherein the source electrode and the gate electrode each include a plurality of layers, wherein, in each of the source electrode and the drain electrode, an uppermost layer is formed of a material that has a smaller difference in work function relative to a material used for the semiconductor layer as compared to a material used for layers respectively constituting the source electrode and the drain electrode other than the uppermost layers, and wherein respective top and side faces of the source electrode and the drain electrode contact the semiconductor layer directly, and the layers respectively constituting the source electrode and the drain electrode other than the uppermost layers are separated from the semiconductor layer by at least one of the second gate insulating layer and the respective uppermost layers of the source electrode and the drain electrode.

Furthermore, to solve the above-mentioned problems, in one aspect of the present invention, a method of manufacturing a semiconductor element includes: forming a first gate insulating layer covering a gate electrode; forming a source electrode and a drain electrode with a gap therebetween on the first gate insulating layer such that, in a plan view, the source electrode and the drain electrode are disposed on respective sides of the gate electrode and both partially overlap the gate electrode through the first gate insulating layer; forming a second gate insulating layer on the first gate insulating layer in at least a region between the source electrode and the drain electrode; and forming a semiconductor layer between and on top of the source electrode and the drain electrode, the semiconductor layer overlapping the gate electrode through the first gate insulating layer, the second gate insulating layer, the source electrode, and the drain electrode, wherein, in the step of forming the source electrode and the drain electrode, the source electrode and the drain electrode are each formed of a plurality of layers, and respective uppermost layers of the source electrode and the drain electrode are formed of a material that has a smaller difference in work function relative to a material used for the semiconductor layer as compared to a material used for layers respectively constituting the source electrode and the drain electrode other than the uppermost layers, and wherein, in the step of forming the second gate insulating layer, the second gate insulating layer is formed such that, in the region between the source electrode and the drain electrode on the first gate insulating layer, a thickness of the second gate insulating layer is greater than respective total thicknesses of the layer of the source electrode other than the uppermost layer and a total thickness of the layer of the drain electrode other than the uppermost layer but less than a total thickness of the source electrode and a total thickness of the drain electrode.

Furthermore, to solve the above-mentioned problems, in one aspect of the present invention, a method of manufacturing a semiconductor element includes: forming a first gate insulating layer covering a gate electrode; forming a source electrode and a drain electrode with a gap therebetween on the first gate insulating layer such that, in a plan view, the source electrode and the drain electrode are disposed on respective sides of the gate electrode and both partially overlap the gate electrode through the first gate insulating layer, and such that the source electrode and the drain electrode each include two layers; forming a second gate insulating layer on the first gate insulating layer in at least a region between the source electrode and the drain electrode; and forming a semiconductor layer between and on top of the source electrode and the drain electrode, the semiconductor layer overlapping the gate electrode through the first gate insulating layer, the second gate insulating layer, the source electrode, and the drain electrode, wherein the step of forming the source electrode and the drain electrode includes: forming, on the first gate insulating layer, a first source electrode layer and a first drain electrode layer that function as adhesion layers with the first gate insulating layer; and forming, respectively on the first source electrode layer and the first drain electrode layer, a second source electrode layer and a second drain electrode layer made of a material that has a smaller difference in work function relative to a material used for the semiconductor layer as compared to a material used for the first source electrode layer and the first drain electrode layer, wherein the step of forming the second gate insulating layer includes: forming, in the region between the source electrode and the drain electrode, a source-side second gate insulating layer that covers a side face of the first source electrode layer, and forming, in the region between the source electrode and the drain electrode, a drain-side second gate insulating layer covering a side face of the first drain electrode layer, wherein, in the steps of forming the source-side second gate insulating layer and the drain-side second gate insulating layer, the source-side second gate insulating layer and the drain-side second gate insulating layer are formed with a gap therebetween; at least a portion of a side face of the second source electrode layer is exposed; and at least a portion of a side face of the second drain electrode layer is exposed.

Furthermore, to solve the above-mentioned problems, in one aspect of the present invention, a method of manufacturing a semiconductor element includes: forming a first gate insulating layer covering a gate electrode; forming a first source electrode layer and a first drain electrode layer with a gap therebetween on the first gate insulating layer such that, in a plan view, the first source electrode layer and the first drain electrode layer are disposed on respective sides of the gate electrode and both partially overlap the gate electrode through the first gate insulating layer; forming, on the first gate insulating layer, on the first source electrode layer, and on the first drain electrode layer, a second gate insulating layer patterned to include openings that respectively expose at least portions of respective top surfaces of the first source electrode layer and the first drain electrode layer; forming, on the second gate insulating layer, a second source electrode layer that is connected to the first source electrode layer via the openings that respectively exposes the first source electrode layer and that is patterned such that, in a plan view, formed with a gap therebetween on either side of the gate electrode, the second source electrode layer partially overlaps the gate electrode through the first gate insulating layer and the first source electrode layer, and forming, on the second gate insulating layer, a second drain electrode layer that is connected to the first drain electrode layer via the openings that respectively expose the first drain electrode layer and that is patterned such that, in a plan view, formed with a gap therebetween on either side of the gate electrode, the second drain electrode layer partially overlaps the gate electrode through the first gate insulating layer and the first drain electrode layer; and forming a semiconductor layer between and on top of the second source electrode layer and the second drain electrode layer, the semiconductor layer overlapping the gate electrode through the first gate insulating layer, the second gate insulating layer, the first source electrode layer, the second source electrode layer, the first drain electrode layer, and the second drain electrode layer, wherein, in the step of forming the second source electrode layer and the second drain electrode layer, the second source electrode layer and the second drain electrode layer are formed of a material that has a smaller difference in work function relative to a material used for the semiconductor layer as compared to a material used for the first source electrode layer and the first drain electrode layer.

Furthermore, to solve the above-mentioned problems, in one aspect of the present invention, a method of manufacturing a semiconductor element includes: forming a first gate insulating layer covering a gate electrode; forming, on the first gate insulating layer, a second gate insulating layer patterned to include openings that expose the first gate insulating layer in regions that, in a plan view, are disposed with a gap therebetween on respective sides of the gate electrode and partially overlap the gate electrode through the first gate insulating layer; forming, by electroless plating, plating layers, respectively, in the openings, as respective portions of a source electrode and a drain electrode such that portions of the plating layers protrude out from the openings; forming, on the second gate insulating layer, surface plating layers that function as respective uppermost layers of the source electrode and the drain electrode, that respectively cover the portions of the plating layers formed in the step of forming the plating layers and protruding from the openings, the second plating layers being disposed with a gap therebetween on respective sides of the gate electrode and both partially overlapping the gate electrode through the first gate insulating layer in a plan view; and forming a semiconductor layer between and on top of the source electrode and the drain electrode, the semiconductor layer overlapping the gate electrode through the first gate insulating layer, the second gate insulating layer, the source electrode, and the drain electrode, wherein, in the step of forming the surface plating layers, the surface plating layers are formed of a material that has a smaller difference in work function relative to a material used for the semiconductor layer as compared to a material used for the respective plating layers formed in the step of forming the plating layers.

### Effects of the Invention

The semiconductor element according to one aspect of the present invention makes it possible to reduce the performance decreases that typically occur when using multilayer source and drain electrodes in a bottom-gate semiconductor element. Moreover, a method for manufacturing a semiconductor element according to one aspect of the present invention makes it possible to manufacture the abovementioned type of semiconductor element.

### BRIEF DESCRIPTION OF THE DRAWINGS

FIG. 1 is a cross-sectional view of an organic TFT according to Embodiment 1 of the present invention.

FIGS. 2(a) to 2(g) are cross-sectional views of the organic TFT according to Embodiment 1 of the present invention illustrating each step of a method for manufacturing the organic TFT.

FIG. 3 is a cross-sectional view of an organic TFT according to a comparative example for the organic TFT according to Embodiment 1 of the present invention.

FIGS. 4(a) and 4(b) are cross-sectional views of organic TFTs according to other comparative examples for the organic TFT according to Embodiment 1 of the present invention.

FIG. 5 is a cross-sectional view of an organic TFT according to Embodiment 2 of the present invention.

FIG. 6 is a graph showing the relationship between the relative permittivity of a gate insulating film (horizontal axis) and the carrier mobility of an organic semiconductor for an organic TFT (vertical axis) in several typical organic TFTs.

FIG. 7 is a cross-sectional view of an organic TFT according to Embodiment 3 of the present invention.

FIG. 8(a) illustrates a process for dripping a semiconductor material using an inkjet in order to form an organic semiconductor layer in the organic TFT according to Embodiment 1 or 2 of the present invention. FIG. 8(b) illustrates a process for dripping a semiconductor material using an inkjet in order to form an organic semiconductor layer in the organic TFT according to Embodiment 3 of the present invention.

FIG. 9 is a cross-sectional view of an organic TFT according to Embodiment 4 of the present invention.

FIG. 10 is a graph showing the relationship between the water contact angle of a gate insulating film (horizontal axis) and the carrier mobility of an organic semiconductor for an organic TFT (vertical axis) in several typical organic TFTs.

FIG. 11(a) illustrates a process for dripping an insulating material between a source electrode and a drain electrode for an organic TFT using an inkjet in order to form a second gate insulating layer in the organic TFT according to Embodiment 5 of the present invention. FIG. 11(b) is a cross-sectional view of the organic TFT according to Embodiment 5 of the present invention.

FIG. 12(a) illustrates a process for dripping an insulating material using an inkjet in order to completely fill the space between the source electrode and the drain electrode 15 in the organic TFT according to any one of Embodiments 1 to 4 of the present invention. FIG. 12(b) illustrates a process for dripping an insulating material using an inkjet in order to partially fill the space between the source electrode and the drain electrode in the organic TFT according to Embodiment 5 of the present invention.

FIGS. 13(a) to 13(f) are cross-sectional views of an organic TFT according to Embodiment 6 of the present invention illustrating each step of a method for manufacturing the organic TFT.

FIG. 14(a) illustrates a process for forming a second gate insulating layer in the organic TFT according to any one of Embodiments 1 to 5 of the present invention by using an inkjet to drip an insulating material. FIG. 14(b) illustrates a process for forming a second gate insulating layer between a first source electrode layer and a second drain electrode layer using a spin coating device in the organic TFT according to Embodiment 6 of the present invention.

FIG. 15 is a cross-sectional view of an organic TFT according to Embodiment 7 of the present invention.

FIG. 16(a) is a cross-sectional view of the organic TFT according to any one of Embodiments 1 to 6 of the present invention illustrating a gate voltage for controlling the organic semiconductor channel being applied from a second layer of the gate electrode. FIG. 16(b) is a cross-sectional view of the organic TFT according to Embodiment 7 of the present invention illustrating a gate voltage for controlling the organic semiconductor channel being applied from a second layer of the gate electrode.

FIGS. 17(a) to 17(d) are cross-sectional views of an organic TFT according to Embodiment 8 of the present invention illustrating each step of a method for manufacturing the organic TFT.

FIGS. 18(a) to 18(d) are cross-sectional views of an organic TFT according to Embodiment 9 of the present invention illustrating each step of a method for manufacturing the organic TFT.

### DETAILED DESCRIPTION OF EMBODIMENTS

### Embodiment 1

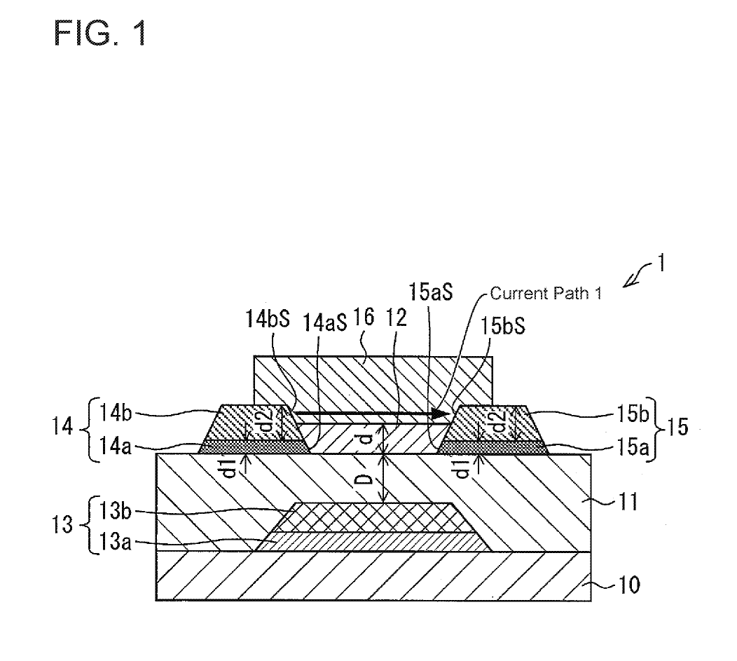

One embodiment of the present invention will be described below with reference to FIGS. 1 to 4.

(Configuration of Organic TFT 1)

FIG. 1 is a cross-sectional view of an organic TFT 1 (a semiconductor element) according to the present embodiment. The organic TFT 1 includes a substrate 10, a first gate insulating layer 11, a second gate insulating layer 12, a gate electrode 13, a source electrode 14, a drain electrode 15, and an organic semiconductor layer 16 (a semiconductor layer).

The organic TFT 1 has a bottom-gate structure in which the gate electrode 13 is formed beneath the source electrode 14 and the drain electrode 15. FIG. 1 also illustrates a current path 1 in the organic semiconductor layer 16. Current flows through current path 1 from the source electrode 14 side to the drain electrode 15 side.

(Substrate 10)

The substrate 10 is made from an insulating material such as glass or plastic and provides a surface on which to form the electrodes and insulating layers of the organic TFT 1. The substrate 10 may be made from a material such as polyethylene terephthalate or a polyimide, for example.

(Gate Electrode 13)

The gate electrode 13 is formed on top of the substrate 10. Here, the gate electrode 13 is disposed on the “top” side of the substrate 10, and the substrate 10 is disposed on the “bottom” side of the gate electrode 13. This convention for the up and down directions will also be used to describe the positional relationships of the other components.

The gate electrode 13 includes a first gate electrode layer 13a that functions as an adhesion layer adhering the gate electrode 13 to the substrate 10 and a second gate electrode layer 13b formed on top of the first gate electrode layer 13a.

The first gate electrode layer 13a is an adhesion layer formed contacting the substrate 10 in order to improve the adhesion between the gate electrode 13 and the substrate 10. The first gate electrode layer 13a is formed using a metal material such as Ti or Cr.

The second gate electrode layer 13b is an electrode formed using a metal material such as aluminum (Al) and is formed on top of the first gate electrode layer 13a. In the organic TFT 1, the second gate electrode layer 13b functions as a contact layer that electrically connects the gate electrode 13 to an external component. The second gate electrode layer 13b may also be formed using a metal material other than Al, such as Au or molybdenum (Mo).

(First Gate Insulating Layer 11)

The first gate insulating layer 11 is formed on top of the substrate 10 and the gate electrode 13 and covers the surfaces thereof. The first gate insulating layer 11 may be formed using an organic insulating material such as polyparavinylphenol (PVP) or an inorganic insulating material such as silicon dioxide (SiO₂), for example.

(Source Electrode 14 and Drain Electrode 15)

The source electrode 14 and the drain electrode 15 are electrodes for use in a FET and are formed with a gap therebetween on top of the first gate insulating layer 11.

The source electrode 14 includes a first source electrode layer 14a that functions as an adhesion layer adhering the source electrode 14 to the first gate insulating layer 11 and a second source electrode layer 14b formed on top of the first source electrode layer 14a.

Similarly, the drain electrode 15 includes a first drain electrode layer 15a that functions as an adhesion layer adhering the drain electrode 15 to the first gate insulating layer 11 and a second drain electrode layer 15b formed on top of the first drain electrode layer 15a.

The first source electrode layer 14a and the first drain electrode layer 15a are adhesion layers formed contacting the first gate insulating layer 11 in order to improve the adhesion between the source electrode 14 and the first gate insulating layer 11 and the adhesion between the drain electrode 15 and the first gate insulating layer 11, respectively. The first source electrode layer 14a and the first drain electrode layer 15a are both formed using a metal material such as Ti or Cr.

The second source electrode layer 14b is an electrode formed using a metal material such as Au and is formed on top of the first source electrode layer 14a. In the organic TFT 1, the second source electrode layer 14b functions as a contact layer that electrically connects the source electrode 14 to an external component and to the organic semiconductor layer 16.

Similarly, the second drain electrode layer 15b is an electrode formed using a metal material such as Au and is formed on top of the first drain electrode layer 15a. In the organic TFT 1, the second drain electrode layer 15b functions as a contact layer that electrically connects the drain electrode 15 to an external component and to the organic semiconductor layer 16.

Moreover, the source electrode 14 and the drain electrode 15 are formed having the same size as one another. Here, let d1 be the thickness of the first source electrode layer 14a and the first drain electrode layer 15a, and let d2 be the thickness of the second source electrode layer 14b and the second drain electrode layer 15b.

The second source electrode layer 14b and the second drain electrode layer 15b may also be formed using a metal material other than Au, such as Al or Mo.

Furthermore, the side faces of the first source electrode layer 14a and the second source electrode layer 14b facing the first drain electrode layer 15 will be referred to as the first source electrode layer side face 14aS and the second source electrode layer side face 14bS, respectively.

Similarly, the side faces of the first drain electrode layer 15a and the second drain electrode layer 15b facing the first source electrode layer 14 will be referred to as the first drain electrode layer side face 15aS and the second drain electrode layer side face 15bS, respectively.

(Second Gate Insulating Layer 12)

The second gate insulating layer 12 is formed on top of the first gate insulating layer 11 and fills the space between the source electrode 14 and the drain electrode 15 arranged with a gap therebetween on the first gate insulating layer 11. Note that in the present specification, the word “fills” does not necessarily imply that a member is formed completely filling a space without any open space left remaining and also includes cases in which a member is formed partially filling a space such that open space is left remaining.

The material used for the second gate insulating layer 12 may be the same insulating material used for the first gate insulating layer 11 or an insulating material different than that used for the first gate insulating layer 11.

Here, let D be the thickness of the first gate insulating layer 11, and let d be the thickness of the second gate insulating layer 12.

The second gate insulating layer 12 is formed such that the thickness d thereof satisfies the relationship given by formula (1) below.

d1<d<d1+d2 (1)

Formula (1) ensures that the second gate insulating layer 12 is formed between the source electrode 14 and the drain electrode 15 such that the second gate insulating layer 12 completely covers the first source electrode layer side face 14aS and the first drain electrode layer side face 15aS, and such that the second gate insulating layer 12 partially covers the second source electrode layer side face 14bS and the second drain electrode layer side face 15bS.

(Organic Semiconductor Layer 16)

The organic semiconductor layer 16 is formed on top of the second gate insulating layer 12, the source electrode 14, and the drain electrode 15 such that the organic semiconductor layer 16 completely covers the surface of the second gate insulating layer 12 and partially covers the surfaces of the source electrode 14 and the drain electrode 15.

Therefore, the organic semiconductor layer 16 is arranged facing the gate electrode 13 and is separated therefrom by the first gate insulating layer 11 and the second gate insulating layer 12. The material used for the organic semiconductor layer 16 may be a small molecule-based organic semiconductor material such as tetracene or a polymer-based organic semiconductor material such as polyparaphenylene vinylene (PPV).

A p-type organic semiconductor is typically used for the organic semiconductor layer 16 in the organic TFT 1. In the present embodiment, the organic semiconductor layer 16 is indeed formed as a p-type organic semiconductor layer.

(Method and Steps for Manufacturing Organic TFT 1)

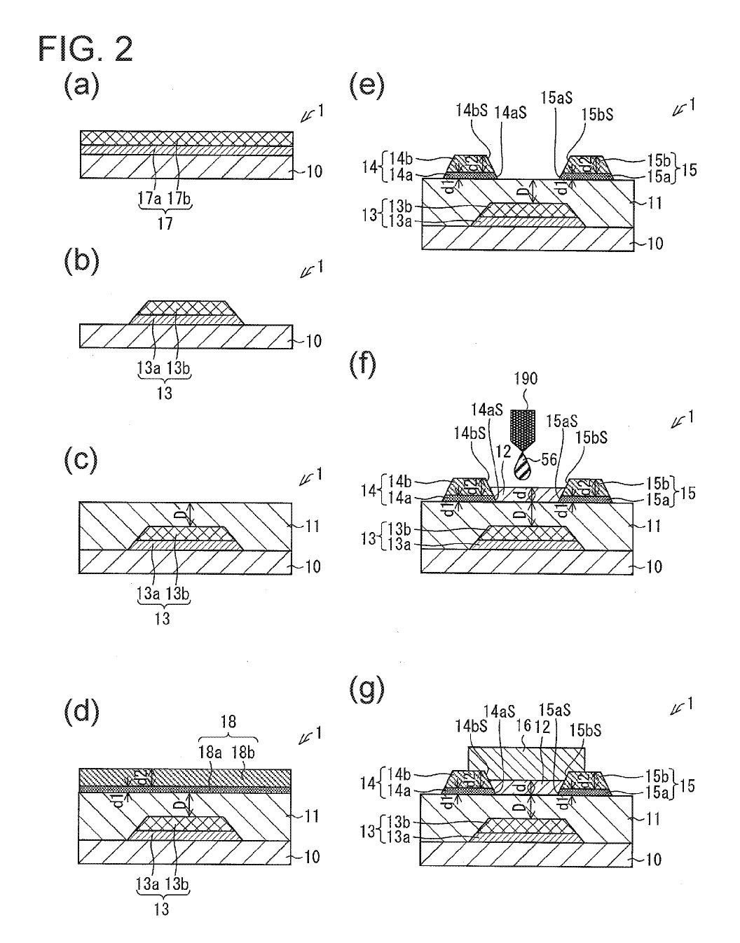

Next, a method for manufacturing the organic TFT 1 according to the present embodiment as well as the manufacturing steps therein will be described with reference to FIGS. 2(a) to 2(g). FIGS. 2(a) to 2(g) are cross-sectional views of the organic TFT 1 illustrating each step of the method for manufacturing the organic TFT 1.

(First Step: Form Base Material Films for Gate Electrode Layers)

As illustrated in FIG. 2(a), before forming the first gate electrode layer 13a and the second gate electrode layer 13b of the gate electrode 13 of the organic TFT 1, a gate electrode layer base material 17 that includes a first gate electrode layer base material 17a and a second gate electrode layer base material 17b is formed as a film over the entire top surface of the substrate 10 (first step, step (a1)).

In the first step, a layer of a material that functions as an adhesion layer is formed as a film with a prescribed thickness over the entire top surface of the substrate 10 using a well-known method such as chemical vapor deposition (CVD) or physical vapor deposition (PVD) in order to form the first gate electrode layer base material 17a. Here, Ti is selected as the material for the first gate electrode layer base material 17a, and the first gate electrode layer base material 17a is formed as a film with a thickness of 10 nm.

Next, a layer of a material that functions as contact layer in the organic TFT 1 is formed as a film with a prescribed thickness over the entire top surface of the first gate electrode layer base material 17a using a well-known method, like with the first gate electrode layer base material 17a, in order to form the second gate electrode layer base material 17b. Here, Al is selected as the material for the second gate electrode layer base material 17b, and the second gate electrode layer base material 17b is formed as a film with a thickness of 300 nm.

(Second Step: Form Gate Electrode)

As illustrated in FIG. 2(b), the gate electrode 13 that includes the first gate electrode layer 13a and the second gate electrode layer 13b is formed using the gate electrode layer base material 17 that includes the first gate electrode layer base material 17a and the second gate electrode layer base material 17b (second step, step (b1)).

In the second step, a photolithography process is applied to the gate electrode layer base material 17 covering the entire top surface of the substrate 10 using a well-known photo-technology to form the gate electrode 13.

In other words, the gate electrode layer base material 17 is patterned using photolithography to form the gate electrode 13. The gate electrode 13 is formed by removing the unnecessary portions of the gate electrode layer base material 17 (that is, the unnecessary portions of the first gate electrode layer base material 17a and the second gate electrode layer base material 17b).

FIG. 2(b) illustrates an example in which the portions of the gate electrode layer base material 17 near both ends of the substrate 10 are removed, and the portion of the gate electrode layer base material 17 near the center of the substrate 10 is left remaining to form the gate electrode 13.

Here, the first gate electrode layer 13a and the second gate electrode layer 13b of the gate electrode 13 correspond, respectively, to the first gate electrode layer base material 17a and the second gate electrode layer base material 17b of the gate electrode layer base material 17.

During the photolithography process, a photoresist mask (not illustrated in the figure) patterned using a well-known photo-technology is formed on top of the gate electrode layer base material 17 at the position corresponding to where the gate electrode 13 should be. This photoresist mask is removed using a process such as ashing after the gate electrode 13 is formed. A chemical cleaning process or the like may also be performed to remove any residue left clinging in the nearby areas.

(Third Step: Form First Gate Insulating Layer)

As illustrated in FIG. 2(c), the first gate insulating layer 11 is formed over the entire top surfaces of the substrate 10 and the gate electrode 13 (third step, step (c1)).

In the third step, a layer of an insulating material is formed as a film with a prescribed thickness over the entire top surfaces of the substrate 10 and the gate electrode 13 using a spin coating device, for example, in order to form the first gate insulating layer 11. Here, PVP is selected as the material for the first gate insulating layer 11, and the first gate insulating layer 11 is formed as a film with a thickness of 500 nm.

Note that the device used to form the first gate insulating layer 11 in the third step is not limited to a spin coating device. Any well-known device for forming a thin film may be used.

(Fourth Step: Form Base Material Films for Source/Drain Electrode Layers)

As illustrated in FIG. 2(d), before forming the first source electrode layer 14a and the second source electrode layer 14b of the source electrode 14 and the first drain electrode layer 15a and the second drain electrode layer 15b of the drain electrode 15, a source/drain electrode layer base material 18 that includes a first source/drain electrode layer base material 18a and a second source/drain electrode layer base material 18b is formed as a film over the entire top surface of the first gate insulating layer 11 (fourth step, step (d1)).

In the fourth step, a layer of a material that functions as an adhesion layer is formed as a film with a prescribed thickness over the entire top surface of the first gate insulating layer 11 using a well-known method, like with the first gate electrode layer base material 17a, in order to form the first source/drain electrode layer base material 18a. Here, Ti is selected as the material for the first source/drain electrode layer base material 18a, and the first source/drain electrode layer base material 18a is formed as a film with a thickness of 10 nm.

Next, a layer of a material that functions as contact layer in the organic TFT 1 is formed as a film with a prescribed thickness over the entire top surface of the first source/drain electrode layer base material 18a using a well-known method, like with the first source/drain electrode layer base material 18a, in order to form the second source/drain electrode layer base material 18b. Here, Au is selected as the material for the second source/drain electrode layer base material 18b, and the second source/drain electrode layer base material 18b is formed as a film with a thickness of 100 nm.

Note that the thickness of the first source/drain electrode layer base material 18a formed in the fourth step is equal to the thickness d1 of the first source electrode layer 14a and the first drain electrode layer 15a of the organic TFT 1. Moreover, the thickness of the second source/drain electrode layer base material 18b is equal to the thickness d2 of the second source electrode layer 14b and the second drain electrode layer 15b of the organic TFT 1.

Therefore, in the present embodiment d1=10 nm and d2=100 nm.

(Fifth Step: Form Source Electrode and Drain Electrode)

As illustrated in FIG. 2(e), the source electrode 14 that includes the first source electrode layer 14a and the second source electrode layer 14b and the drain electrode 15 that includes the first drain electrode layer 15a and the second drain electrode layer 15b are formed from the source/drain electrode layer base material 18 that includes the first source/drain electrode layer base material 18a and the second source/drain electrode layer base material 18b (fifth step, step (e1)).

In the fifth step, a photolithography process is applied to the source/drain electrode layer base material 18 covering the entire top surface of the first gate insulating layer 11 using a well-known photo-technology to form the source electrode 14 and the drain electrode 15.

In other words, the source/drain electrode layer base material 18 is patterned using photolithography to form the source electrode 14 and the drain electrode 15. The source electrode 14 and the drain electrode 15 are formed with a gap therebetween by removing the unnecessary portions of the source/drain electrode layer base material 18 (that is, the unnecessary portions of the first source/drain electrode layer base material 18a and the second source/drain electrode layer base material 18b).

Note that in FIG. 2(e), the source electrode 14 is arranged on a side facing one of the two side faces of the gate electrode 13 in the horizontal direction (that is, on the left side), and the drain electrode 15 is arranged on a side facing the other of the two side faces of the gate electrode 13 (that is, on the right side).

Here, the first source electrode layer 14a and the first drain electrode layer 15a correspond to the first source/drain electrode layer 18a. Therefore, the thickness of the first source electrode layer 14a and the first drain electrode layer 15a is equal to d1=10 nm.

Similarly, the second source electrode layer 14b and the second drain electrode layer 15b correspond to the first source/drain electrode layer 18b. Therefore, the thickness of the second source electrode layer 14b and the second drain electrode layer 15b is equal to d2=100 nm.

During the photolithography process, a photoresist mask (not illustrated in the figure) patterned using a well-known photo-technology is formed on top of the source/drain electrode layer base material 18 at the positions corresponding to where the source electrode 14 and the drain electrode 15 should be. This photoresist mask is removed using a process such as ashing after the source electrode 14 and the drain electrode 15 are formed. A chemical cleaning process or the like may also be performed to remove any residue left clinging in the nearby areas.

(Sixth Step: Form Second Gate Insulating Layer)

As illustrated in FIG. 2(f), the second gate insulating layer 12 is formed on top of the first gate insulating layer 11 and fills the space between the source electrode 14 and the drain electrode 15 arranged with a gap therebetween on the first gate insulating layer 11 (sixth step, step (f1)).

In the sixth step, the second gate insulating layer 12 is formed filling the space between the source electrode 14 and the drain electrode 15 by forming a layer of an insulating material as a film with a prescribed thickness over the entire top surface of the first gate insulating layer 11 between the source electrode 14 and the drain electrode 15 using an inkjet 190 to drip an insulating material 56.

In the present embodiment, the same PVP material used for the first gate insulating layer 11 is selected as the material for the second gate insulating layer 12, and the second gate insulating layer 12 is formed as a film with a thickness d of 50 nm.

The value for the thickness d is selected such that the relationship given above by formula (1) is satisfied. Here, d1=10 nm, d2=100 nm, and d=50 nm, and therefore formula (1) is indeed satisfied, with d1=10 nm<d=50 nm<d1+d2=110 nm.

Therefore, the second gate insulating layer 12 is formed between the source electrode 14 and the drain electrode 15 such that the second gate insulating layer 12 completely covers the first source electrode layer side face 14aS and the first drain electrode layer side face 15aS, and such that the second gate insulating layer 12 partially covers the second source electrode layer side face 14bS and the second drain electrode layer side face 15bS.

Between the process for forming the first gate insulating layer and the process for forming the second gate insulating layer, an additional surface treatment process may be performed in which a surface treatment is applied to the first gate insulating layer 11 obtained from the process for forming the first gate insulating layer in order to make the surface energy of the first gate insulating layer 11 greater than the surface energy of the second gate insulating layer 12. The effect achieved due to the difference between the surface energies of the first gate 11 and the second gate insulating layer 12 will be described in more detail in Embodiments 3 and 4.

(Seventh Step: Form Organic Semiconductor Layer)

As illustrated in FIG. 2(g), the organic semiconductor layer 16 is formed on top of the second gate insulating layer 12, the source electrode 14, and the drain electrode 15 such that the organic semiconductor layer 16 completely covers the surface of the second gate insulating layer 12 and partially covers the surfaces of the source electrode 14 and the drain electrode 15 (seventh step, step (g1)).

In the seventh step, using a well-known method such as vacuum deposition (or an inkjet method or a spin coating method, for example), a layer of an organic semiconductor material is formed as a film on top of the second gate insulating layer 12, the source electrode 14, and the drain electrode 15, completely covering the surface of the second gate insulating layer 12 and partially covering the surfaces of the source electrode 14 and the drain electrode 15, in order to form the organic semiconductor layer 16.

Therefore, the organic semiconductor layer 16 is formed facing the gate electrode 13 and is separated therefrom by the first gate insulating layer 11 and the second gate insulating layer 12. In the present embodiment, PPV is selected as the material for the organic semiconductor layer 16, and the organic semiconductor layer is formed as a film with a thickness of 200 nm.

The organic TFT 1 of the present embodiment is formed using the first to seventh manufacturing steps described above and illustrated in FIGS. 2(a) to 2(g).

Before the process for forming the organic semiconductor layer 16, an additional surface treatment process may be performed in which a surface treatment is applied to the second gate insulating layer 12 obtained from the process for forming the second gate insulating layer in order to make the surface energy of the second gate insulating layer 12 greater than the surface energy of the first gate insulating layer 11. The effect achieved due to the difference between the surface energies of the first gate 11 and the second gate insulating layer 12 will be described in more detail in Embodiments 3 and 4.

(Organic TFT 101 According to Comparative Example)

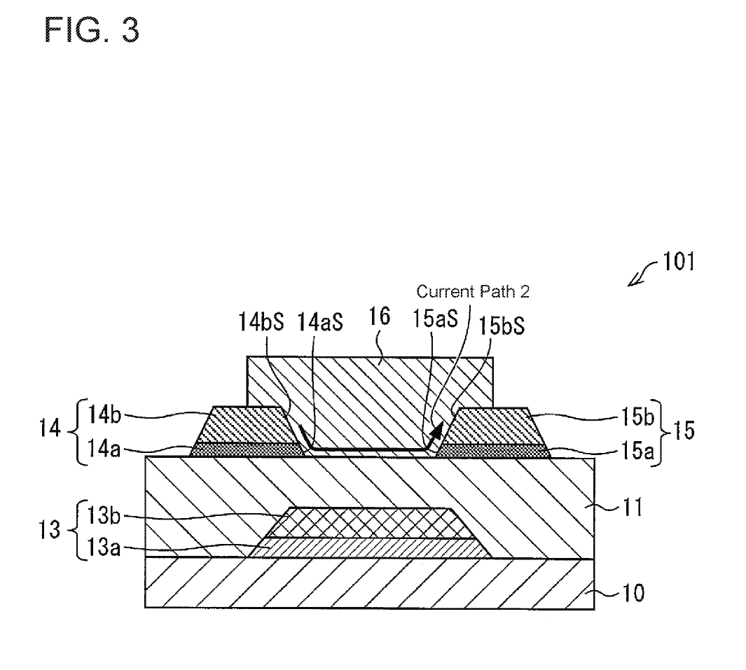

Next, an organic TFT 101 will be described with reference to FIG. 3 as a comparative example for the organic TFT 1 of the present embodiment. FIG. 3 is a cross-sectional view of the organic TFT 101 according to this comparative example. The same configuration illustrated for the organic TFT 101 in FIG. 3 is disclosed in Non-Patent Document 2.

The organic TFT 101 according to this comparative example includes a substrate 10, a first gate insulating layer 11, a gate electrode 13, a source electrode 14, a drain electrode 15, and an organic semiconductor layer 16. Here, the components of the organic TFT 101 according to this comparative example are the same as the components of the organic TFT 1 according to the present embodiment, and therefore the same reference characters are used for these components.

The organic TFT 101 according to this comparative example does not include the second gate insulating layer 12 included in the organic TFT 1 of the present embodiment, and the space filled by the second gate insulating layer 12 in the organic TFT 1 of the present embodiment is instead filled by the organic semiconductor layer 16.

FIG. 3 also illustrates a current path 2 in the organic semiconductor layer 16 of the organic TFT 101 according to this comparative example. Current flows through the current path 2 from the source electrode 14 side to the drain electrode 15 side.

In the organic TFT 101, the organic semiconductor layer 16 is electrically connected to the first source electrode layer 14a of the source electrode 14 and to the first drain electrode layer 15a of the drain electrode 15. The organic semiconductor layer 16 is also electrically connected to the second source electrode layer 14b of the source electrode 14 and to the second drain electrode layer 15b of the drain electrode 15.

Here, the organic semiconductor layer 16 of the organic TFT 101 is a p-type organic semiconductor with a work function on the order of 5.0 eV.

Moreover, the second source electrode layer 14b and the second drain electrode layer 15b that respectively function as the electrodes of the source electrode 14 and the drain electrode 11 are formed using a material such as Au. The second source electrode layer 14b and the second drain electrode layer 15b have work functions on the order of 4.8 eV when formed using Au.

The second source electrode layer 14b and the second drain electrode layer 15b are not limited to Au and may also be formed using a material such as copper (Cu) or nickel (Ni). The second source electrode layer 14b and the second drain electrode layer 15b have work functions on the order of 4.7 eV when formed using Cu. Moreover, the second source electrode layer 14b and the second drain electrode layer 15b have work functions on the order of 5.2 eV when formed using Ni.

Therefore, the organic semiconductor layer 16 has a work function of approximately the same magnitude as the second source electrode layer 14b and the second drain electrode layer 15b and can make good contact therewith. As a result, the contact resistance between the organic semiconductor layer 16 and the second source electrode layer 14b and between the organic semiconductor layer 16 and the second drain electrode layer 15b is low, thereby making it possible for large amounts of current to flow therebetween.

Meanwhile, the first source electrode layer 14a and the first drain electrode layer 15a that function as adhesion layers are formed using a material such as Ti. The first source electrode layer 14a and the first drain electrode layer 15a have work functions on the order of 4.0 eV.

Therefore, the organic semiconductor layer 16 has a work function of different magnitude than the first source electrode layer 14a and the second drain electrode layer 15a and cannot make good contact therewith. As a result, the contact resistance between the organic semiconductor layer 16 and the first source electrode layer 14a and between the organic semiconductor layer 16 and the first drain electrode layer 15 a is high, and large amounts of current cannot flow therebetween.

In other words, the contact resistance between the organic semiconductor layer 16 and the second source electrode layer 14b is lower than the contact resistance between the organic semiconductor layer 16 and the first source electrode layer 14a. Similarly, the contact resistance between the organic semiconductor layer 16 and the second drain electrode layer 15b is lower than the contact resistance between the organic semiconductor layer 16 and the first drain electrode layer 15a.

In the organic semiconductor layer 16, current flows between the source electrode 14 and the drain electrode 15 through a channel formed near the interface between the organic semiconductor layer 16 and the first gate insulating layer 11. This current that flows through the organic semiconductor layer 16 from the source electrode 14 to the drain electrode 15 starts from the second source electrode layer 14b of the source electrode 14, proceeds from the source electrode 14 to the drain electrode 11 through the channel formed near the interface between the organic semiconductor layer 16 and the first gate insulating layer 11 (that is, through the current path 2), and then reaches the second drain electrode layer 15b of the drain electrode 15.

Therefore, in the organic TFT 101 according to this comparative example, the amount of current that flows through the current path 2 in the organic semiconductor layer 16 decreases due to the presence of the first source electrode layer 14a and the first drain electrode layer 15a that function as adhesion layers. As a result, the organic TFT 101 suffers from a decrease in performance.

(Effects of the Organic TFT 1)

Next, the effects of the organic TFT 1 of the present embodiment will be described with reference to the current path 1 illustrated in FIG. 1.

The organic TFT 1 of the present embodiment includes the second gate insulating layer 12 between the source electrode 14 and the drain electrode 15. In this regard, the organic TFT 1 of the present embodiment differs from the organic TFT 101 of the comparative example.

Here, like in the organic TFT 101 of the comparative example, the contact resistance between the organic semiconductor layer 16 and the second source electrode layer 14b is lower than the contact resistance between the organic semiconductor layer 16 and the first source electrode layer 14a. Similarly, the contact resistance between the organic semiconductor layer 16 and the second drain electrode layer 15b is lower than the contact resistance between the organic semiconductor layer 16 and the first drain electrode layer 15a.

In the organic semiconductor layer 16, current flows between the source electrode 14 and the drain electrode 15 through a channel formed near the interface between the organic semiconductor layer 16 and the second gate insulating layer 12. This current that flows through the organic semiconductor layer 16 from the source electrode 14 to the drain electrode 15 starts from the second source electrode layer 14b of the source electrode 14, proceeds from the source electrode 4 to the drain electrode 15 through the channel formed near the interface between the organic semiconductor layer 16 and the second gate insulating layer 12 (that is, through the current path 1), and then reaches the second drain electrode layer 15b of the drain electrode 15.

Here, the current path 1 is positioned along the top surface of the second gate insulating layer 12 that completely covers the first source electrode layer side face 14aS and the first drain electrode layer side face 15aS. As a result, in the current path 1 the negative effects due to the contact resistance between the organic semiconductor layer 16 and the first source electrode layer 14a and between the organic semiconductor layer 16 and the first drain electrode layer 15a are removed.

In the organic TFT 1 of the present embodiment, current flows through the current path 1, which has a lower contact resistance than the current path 2 in the organic TFT 101 of the comparative example. As a result, the amount of current that can flow through the organic semiconductor layer 16 through the current path 1 is greater than the amount of current that can flow through the current path 2 in the organic TFT 101 of the comparative example.

Therefore, including the additional second gate insulating layer 12 in the organic TFT 1 of the present embodiment makes it possible to reduce performance decreases in the organic TFT 1.

Furthermore, the same effect can be achieved in a semiconductor element (such as an inorganic TFT) that has the same structure as the organic TFT 1 of the present embodiment but is instead manufactured using an inorganic semiconductor layer that has the same physical properties (such as work function) as the organic semiconductor layer 16 of the present embodiment.

(Organic TFTs 101a and 101b According to Other Comparative Examples)

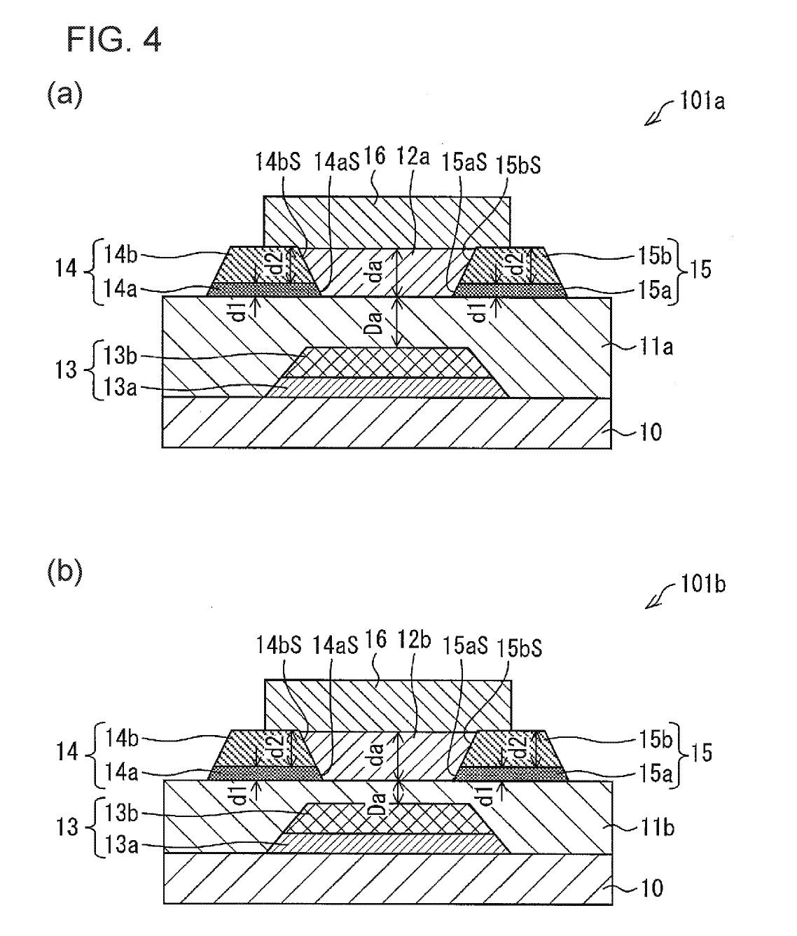

Next, the organic TFT 101a illustrated in FIG. 4(a) and the organic TFT 101b illustrated in FIG. 4(b) will be described as further comparative examples for the organic TFT 1 of the present embodiment.

FIG. 4(a) is a cross-sectional view of the organic TFT 101a according to another comparative example for the organic TFT 1 of the present embodiment. The organic TFT 101a includes a substrate 10, a first gate insulating layer 11a, a second gate insulating layer 12a, a gate electrode 13, a source electrode 14, a drain electrode 15, and an organic semiconductor layer 16.

Here, except for the first gate insulating layer 11a and the second gate insulating layer 12a, the components of the organic TFT 101a according to this comparative example are the same as the components of the organic TFT 1 according to the present embodiment, and therefore the same reference characters are used for these components that are the same.

The second gate insulating layer 12a of the organic TFT 101a is formed between the source electrode 14 and the drain electrode 15 and has the same configuration as the planarizing layer disclosed in Patent Document 1.

In other words, the thickness da of the second gate insulating layer 12a of the organic TFT 101a satisfies da=d1+d2.

Moreover, in the first gate insulating layer 11a, the thickness Da from the top surface of the second gate electrode layer 13b to the top surface of the first gate insulating layer 11a satisfies the relationship Da≈da. In other words, the first gate insulating layer 11a of the organic TFT 101a is a thick insulating film with approximately the same thickness as the second gate insulating layer 12a.

In this case, the first gate insulating layer 11a and the second gate insulating layer 12a of the organic TFT 101a are both thick, thereby decreasing the amount of current that flows through the organic semiconductor layer 16 and decreasing the performance of the organic TFT 101.

FIG. 4(b) is a cross-sectional view of the organic TFT 101b according to another comparative example for the organic TFT 1 of the present embodiment. The organic TFT 101b includes a substrate 10, a first gate insulating layer 11b, a second gate insulating layer 12b, a gate electrode 13, a source electrode 14, a drain electrode 15, and an organic semiconductor layer 16.

Here, except for the first gate insulating layer 11b and the second gate insulating layer 12b, the components of the organic TFT 101b according to this comparative example are the same as the components of the organic TFT 1 according to the present embodiment, and therefore the same reference characters are used for these components that are the same.

The second gate insulating layer 12b of the organic TFT 101b is formed between the source electrode 14 and the drain electrode 15 and has the same configuration as the planarizing layer disclosed in Patent Document 1.

In other words, like in the second gate insulating layer 12a of the organic TFT 101a, the thickness db of the second gate insulating layer 12b of the organic TFT 101b satisfies db=d1+d2.

Moreover, in the first gate insulating layer 11b, the thickness Db from the top surface of the second gate electrode layer 13b to the top surface of the first gate insulating layer 11b satisfies the relationship Db<<db. In other words, the second gate insulating layer 12b of the organic TFT 101b is a thin insulating film with a thickness much smaller than the first gate insulating layer 11b.

In this case, the second gate insulating layer 12b of the organic TFT 101b is thinner than the second gate insulating layer 12a of the organic TFT 101a. Therefore, the organic TFT 101b allows a larger amount of current to flow than does the organic TFT 101a, thereby making it possible to achieve better performance than in the organic TFT 101a.

However, because the second gate insulating layer 12b is thin, the dielectric strength between the gate electrode 13 and the source electrode 14 and the dielectric strength between the gate electrode 13 and the drain electrode 15 are lower in the organic TFT 101b than in the organic TFT 101a. Therefore, the organic TFT 101b is less resistant to high voltages than the organic TFT 101a and suffers in terms of the reliability of the device.

Meanwhile, in the organic TFT 1 of the present embodiment, forming the second gate insulating layer 12 that satisfies the formula (1) given above makes it possible to achieve both good performance and good reliability in the device. In other words, the organic TFT 1 of the present embodiment achieves better device performance than the organic TFTs 101a and 101b of the comparative examples.

### Embodiment 2

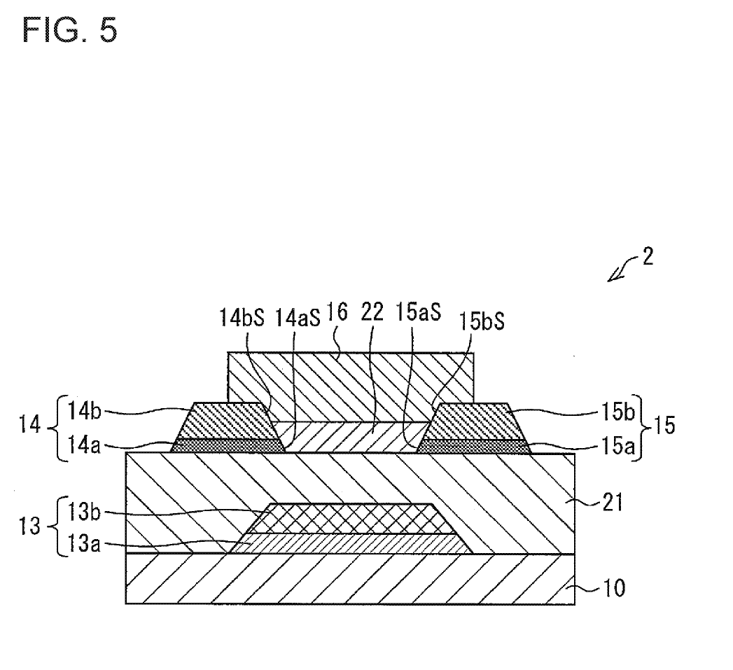

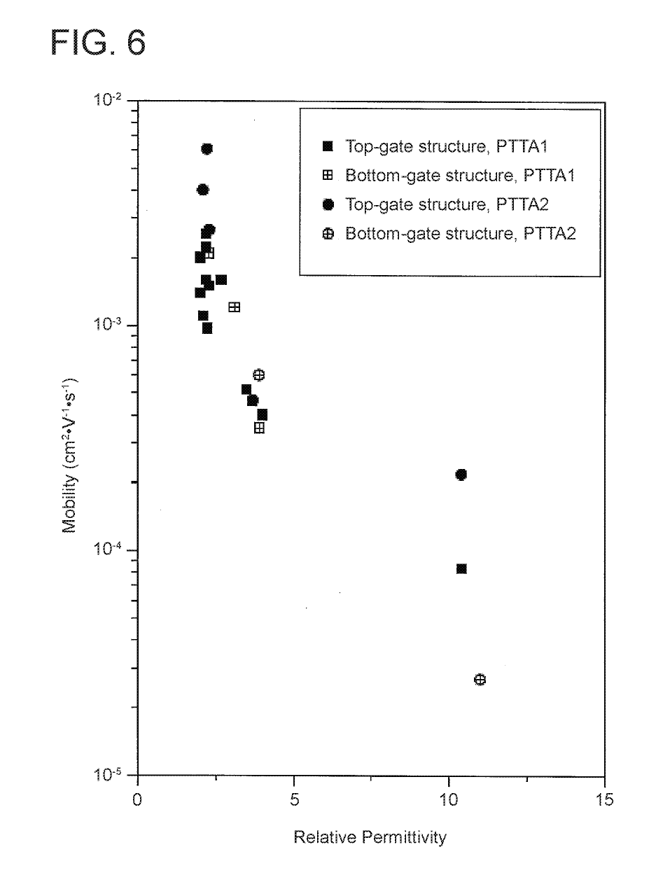

Next, another embodiment of the present invention will be described with reference to FIGS. 5 and 6. For convenience, the same reference characters are used for components that have the same functions as components described in the previous embodiment, and descriptions of those components will be omitted here.

(Configuration of Organic TFT 2)

FIG. 5 is a cross-sectional view of an organic TFT 2 (a semiconductor element) according to the present embodiment. The organic TFT 2 includes a substrate 10, a first gate insulating layer 21, a second gate insulating layer 22, a gate electrode 13, a source electrode 14, a drain electrode 15, and an organic semiconductor layer 16.

Here, except for the first gate insulating layer 21 and the second gate insulating layer 22, the components of the organic TFT 2 of Embodiment 2 are the same as the components of the organic TFT 1 of Embodiment 1, and therefore the same reference characters are used for these components that are the same.

(First Gate Insulating Layer 21)

The first gate insulating layer 21 is formed on top of the substrate 10 and the gate electrode 13 and covers the surfaces thereof.

Here, the first gate insulating layer 21 of the organic TFT 2 is formed using a material with a higher permittivity than the material used for the second gate insulating layer 22. In the present embodiment, PVP with a relative permittivity εᵣ₁=3.6 is used as the material for the first gate insulating layer 21.

Therefore, the permittivity ε₁ of the first gate insulating layer 21 is given by ε₁=ε₀×ε₁=3.6×ε₀, where ε₀ is the permittivity of free space.

The material used for the first gate insulating layer 21 is not limited to PVP, and any high permittivity material (high-κ material) that exhibits sufficient insulating performance and has a higher permittivity than the second gate insulating layer 22 may be used.

(Second Gate Insulating Layer 22)

The second gate insulating layer 22 is formed on top of the first gate insulating layer 21 and fills the space between the source electrode 14 and the drain electrode 15 arranged with a gap therebetween on the first gate insulating layer 21. Here, the second gate insulating layer 22 is formed using a material with a lower permittivity than the material used for the first gate insulating layer 21. In the present embodiment, CYTOP (an amorphous fluororesin, registered trademark, Asahi Glass Co., Ltd.) with a relative permittivity εᵣ₂=2.0 is used as the material for the second gate insulating layer 22.

Therefore, the permittivity ε₂ of the second gate insulating layer 22 is given by ε₂=ε₀×εᵣ₂=2.0×ε₀.

The material used for the second gate insulating layer 22 is not limited to CYTOP, and any low permittivity material (low-κ material) that exhibits sufficient insulating performance and has a lower permittivity than the first gate insulating layer 21 may be used.

(Effects of Organic TFT 2)

Next, the effects of the organic TFT 2 of the present embodiment will be described with reference to FIG. 6. FIG. 6 is a graph showing the relationship between the relative permittivity of a gate insulating film (horizontal axis) and the carrier mobility of an organic semiconductor for an organic TFT (vertical axis) in several typical organic TFTs.

The graph in FIG. 6 is disclosed in Non-Patent Document 3 and shows data for various top-gate and bottom-gate organic TFTs.

Here, “top-gate organic TFT” refers to an organic TFT in which the gate electrode is arranged above the source electrode and the drain electrode. Similarly, “bottom-gate organic TFT” refers to an organic TFT in which the gate electrode is arranged below the source electrode and the drain electrode. The organic TFT 2 of the present embodiment employs a bottom-gate structure.

Furthermore, FIG. 6 shows data for organic TFTs formed using two different polytriarylamine (PTTA) materials, PTTA1 and PTTA2.

As shown in FIG. 6, regardless of the semiconductor material used, the carrier mobility of an organic semiconductor tends to increase as the relative permittivity of the gate insulating film used in the organic TFT decreases. Therefore, the carrier mobility of an organic semiconductor can be increased by decreasing the permittivity of the gate insulating film contacting that organic semiconductor.

In the organic TFT 2, the second gate insulating layer 22 that contacts the organic semiconductor layer 16 is formed using a low permittivity material, thereby making it possible to increase the carrier mobility of the organic semiconductor layer 16. This, in turn, makes it possible to improve the performance of the organic TFT 2.

Meanwhile, in conventional field-effect transistors that employ inorganic semiconductor layers made from a material such as silicon (Si), a high permittivity material (that is, a material with a high relative permittivity) is typically used as the material for the gate insulating layer in order to achieve the desired current characteristics in the transistor.

This means that the amount of current that flows from the source to the drain in these field-effect transistors is defined by the capacitance of the gate insulating layer. Therefore, the amount of current that flows from the source to the drain can be increased by increasing the capacitance of the gate insulating layer.

Here, the capacitance C of the gate insulating layer is given below by formula (2), where d is the thickness of the gate insulating layer, S is the surface area of the gate insulating layer, and ε is the permittivity of the gate insulating layer.

C=(ε×S)/d (2)

Formula (2) says that for a fixed gate insulating layer thickness d, the current characteristics of the field-effect transistor can be improved by increasing the gate insulating layer capacitance C—that is, by using an insulating material with a large permittivity ε as the material for the gate insulating layer.

Formula (2) also says that for a fixed gate insulating layer capacitance C, using an insulating material with a larger permittivity ε as the material for the gate insulating layer makes it possible to increase the gate insulating layer thickness d, thereby making it possible to design the field-effect transistor with sufficient insulating performance to prevent leakage currents and dielectric breakdown.

Therefore, in the organic TFT 2, a material with a high permittivity ε is used as the material for the first gate insulating layer 21, which does not contact the organic semiconductor layer 16. As a result, like in conventional field-effect transistors that employ inorganic semiconductor layers, both good current characteristics and good insulating performance can be achieved in the organic TFT 2 as well.

In other words, in the organic TFT 2, forming the second gate insulating layer 22 that contacts the organic semiconductor layer 16 using a material with a lower permittivity than the first gate insulating layer 21 (here, a material with ε₂=2.0×ε₀) and forming the first gate insulating layer 21 that does not contact the organic semiconductor layer 16 using a material with a higher permittivity than the second gate insulating layer 22 (here, a material with ε₁=3.6×ε₀) makes it possible to achieve both good insulating performance and good overall performance in the organic TFT 2.

### Embodiment 3

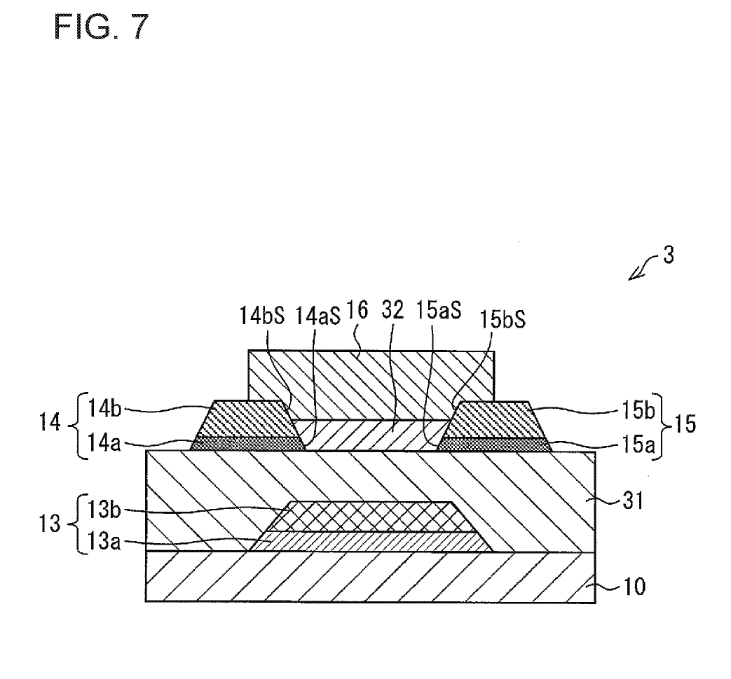

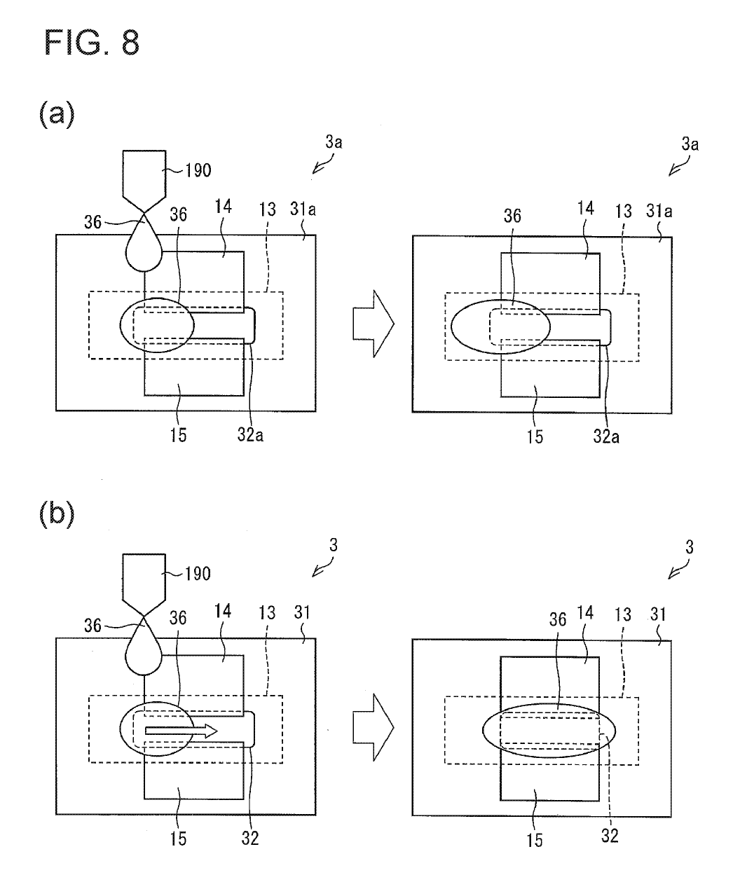

Next, another embodiment of the present invention will be described with reference to FIGS. 7 and 8. For convenience, the same reference characters are used for components that have the same functions as components described in the previous embodiments, and descriptions of those components will be omitted here.

(Configuration of Organic TFT 3)

FIG. 7 is a cross-sectional view of an organic TFT 3 (a semiconductor element) according to the present embodiment. The organic TFT 3 includes a substrate 10, a first gate insulating layer 31, a second gate insulating layer 32, a gate electrode 13, a source electrode 14, a drain electrode 15, and an organic semiconductor layer 16.

Here, except for the first gate insulating layer 31 and the second gate insulating layer 32, the components of the organic TFT 3 of Embodiment 3 are the same as the components of the organic TFT 1 of Embodiment 1, and therefore the same reference characters are used for these components that are the same.

(First Gate Insulating Layer 31)

The first gate insulating layer 31 is formed on top of the substrate 10 and the gate electrode 13 and covers the surfaces thereof.

Here, the first gate insulating layer 31 of the organic TFT 3 is formed to have a smaller surface energy than the second gate insulating layer 32. In other words, a material that has a lower surface energy than the material used for the second gate insulating layer 32 is selected as the material for the first gate insulating layer 31.

Alternatively, the first gate insulating layer 31 of the organic TFT 3 may be formed using the same material used for the second gate insulating layer 32.

In this case, the second gate insulating layer 32 can be formed with a greater surface energy than the first gate insulating layer 31 by irradiating the surface of the second gate insulating layer 32 with UV light to reform that surface. The second gate insulating layer 32 may also be formed having a greater surface energy than the first gate insulating layer 31 by applying a monolayer film such as a silane coupling agent to the surface of the second gate insulating layer 32.

(Second Gate Insulating Layer 32)

The second gate insulating layer 32 is formed on top of the first gate insulating layer 31 and fills the space between the source electrode 14 and the drain electrode 15 arranged with a gap therebetween on the first gate insulating layer 31.

Here, the second gate insulating layer 32 of the organic TFT 3 is formed to have a greater surface energy than the first gate insulating layer 31. In other words, a material that has a higher surface energy than the material used for the first gate insulating layer 31 is selected as the material for the second gate insulating layer 32.

Here, the surface energy ES1 of the first gate insulating layer 31 and the surface energy ES2 of the second gate insulating layer 32 satisfy the relationship ES1<ES2.

Alternatively, as described above for the first gate insulating layer 31, the second gate insulating layer 32 may be formed using the same material used for the first gate insulating layer 31.

(Effects of the Organic TFT 3)

Next, the effects of the organic TFT 3 of the present embodiment will be described with reference to FIG. 8(b). FIG. 8(b) illustrates a process for dripping a semiconductor material 36 using an inkjet 190 in the organic TFT 3 in order to form the organic semiconductor layer 16 on top of the second gate insulating layer 32, the source electrode 14, and the drain electrode 15 such that the organic semiconductor layer 16 completely covers the surface of the second gate insulating layer 32 and partially covers the surfaces of the source electrode 14 and the drain electrode 15 (this process corresponds to the seventh step (step (g1)) in Embodiment 1).

First, however, consider the organic TFT 3a illustrated in FIG. 8(a). The organic TFT 3a is the same as the organic TFT according to Embodiment 1 or 2 as described above. Here, the organic TFT 3a is the same as the organic TFT 1 of Embodiment 1, for example.

Except for the first gate insulating layer 31a and the second gate insulating layer 32a, the components of the organic TFT 3a according to this comparative example are the same as the components of the organic TFT 3 according to Embodiment 3, and therefore the same reference characters are used for these components that are the same.

In the organic TFT 3a, the surface energy of the second gate insulating layer 32a is equal to the surface energy of the first gate insulating layer 31. In other words, the surface energy ES1a of the first gate insulating layer 31a and the surface energy ES2a of the second gate insulating layer 32a satisfy the relationship ES1a=ES2a.

In this regard, the organic TFT 3a according to this comparative example is different from the organic TFT 3 of the present embodiment, in which the surface energy ES2 of the second gate insulating layer 32 is greater than the surface energy ES1 of the first gate insulating layer 31 (that is, ES1<ES2).

FIG. 8(a) illustrates a process for dripping a semiconductor material 36 using an inkjet 190 in the organic TFT 3 a in order to form the organic semiconductor layer 16 on top of the second gate insulating layer 32a, the source electrode 14, and the drain electrode 15 such that the organic semiconductor layer 16 completely covers the surface of the second gate insulating layer 32a and partially covers the surfaces of the source electrode 14 and the drain electrode 15 (this process corresponds to the seventh step (step (g1)) in Embodiment 1).

Note that because a high alignment precision inkjet may not necessarily be used as the inkjet 190, the semiconductor material 36 may not necessarily be dripped onto the region corresponding to the top surface of the second gate insulating layer 32a when dripping that semiconductor material 36 using the inkjet 190.

Therefore, as illustrated in FIG. 8(a), some of the semiconductor material 36 dripped using the inkjet 190 may be dripped outside of the region corresponding to the top surface of the second gate insulating layer 32a and may instead be positioned on top of the first gate insulating layer 31a.

Recall that in the organic TFT 3a, the surface energy ES2a of the second gate insulating layer 32a is equal to the surface energy ES1a of the first gate insulating layer 31a. As a result, the second gate insulating layer 32a and the first gate insulating layer 31a both form the same contact angle with a drop of the semiconductor material 36. In other words, the second gate insulating layer 32a and the first gate insulating layer 31a both exhibit the same wettability to a drop of the semiconductor material 36.

Therefore, the portion of the semiconductor material 36 dripped onto the first gate insulating layer 31a does not spread back towards the second gate insulating layer 32a and instead remains at that original position, eventually drying and crystallizing as time passes.

As a result, in some cases the organic semiconductor layer 16 may not be formed uniformly across the region corresponding to the top surface of the second gate insulating layer 32a in the organic TFT 3a.

Next, the effects of the organic TFT 3 of the present embodiment will be described with reference to FIG. 8(b). As illustrated in FIG. 8(b), some of the semiconductor material 36 dripped using the inkjet 190 may be dripped outside of the region corresponding to the top surface of the second gate insulating layer 32 and may instead be positioned on top of the first gate insulating layer 31.

However, in the organic TFT 3 the surface energy ES2 of the second gate insulating layer 32 is greater than the surface energy ES1 of the first gate insulating layer 31. Therefore, the second gate insulating layer 32 forms a smaller contact angle with a drop of the semiconductor material 36 than does the first gate insulating layer 31. In other words, the second gate insulating layer 32 exhibits higher wettability to a drop of the semiconductor material 36 than does the first gate insulating layer 31.

As a result, the portion of the semiconductor material 36 on top of the first gate insulating layer 31 recedes from the surface of the first gate insulating layer 31 and spreads out towards the second gate insulating layer 32. Furthermore, the portion of the semiconductor material 36 dripped onto the first gate insulating layer 31 moves back towards the second gate insulating layer 32, eventually drying and crystallizing as time passes.

Therefore, the organic semiconductor layer 16 is formed uniformly across the region corresponding to the top surface of the second gate insulating layer 32 in the organic TFT 3. This makes it possible to further improve the performance of the organic TFT 3.

### Embodiment 4

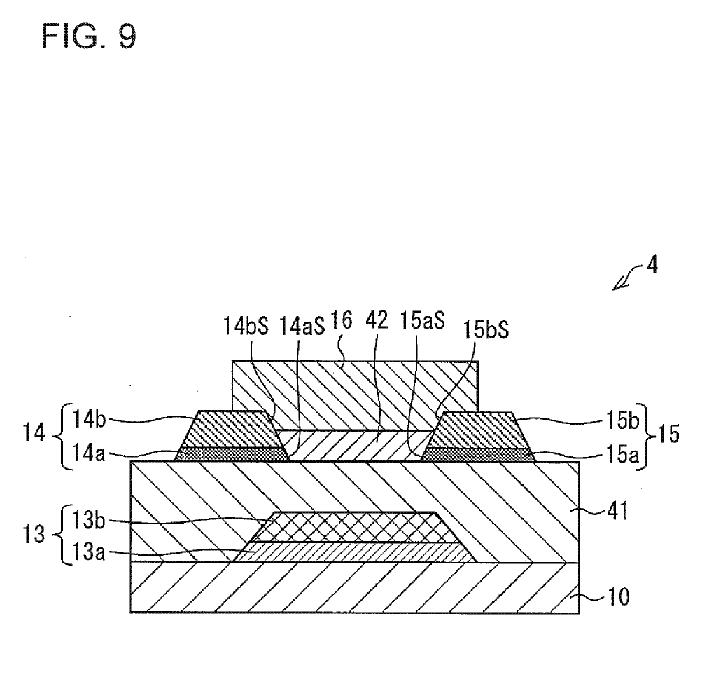

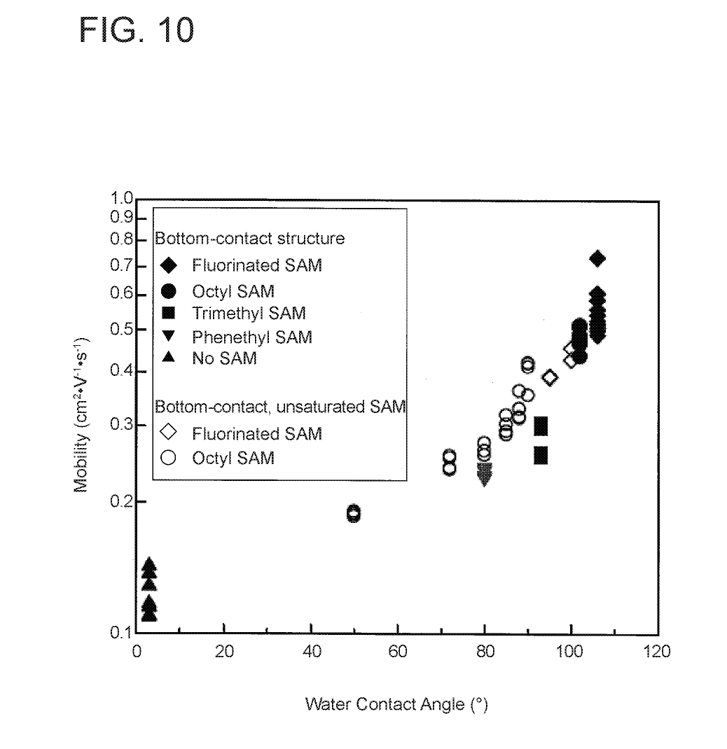

Next, another embodiment of the present invention will be described with reference to FIGS. 9 and 10. For convenience, the same reference characters are used for components that have the same functions as components described in the previous embodiments, and descriptions of those components will be omitted here.

(Configuration of an Organic TFT 4)

FIG. 9 is a cross-sectional view of an organic TFT 4 (a semiconductor element) according to the present embodiment. The organic TFT 4 includes a substrate 10, a first gate insulating layer 41, a second gate insulating layer 42, a gate electrode 13, a source electrode 14, a drain electrode 15, and an organic semiconductor layer 16.

Here, except for the first gate insulating layer 41 and the second gate insulating layer 42, the components of the organic TFT 4 of Embodiment 4 are the same as the components of the organic TFT 1 of Embodiment 1, and therefore the same reference characters are used for these components that are the same.

(First Gate Insulating Layer 41)

The first gate insulating layer 41 is formed on top of the substrate 10 and the gate electrode 13 and covers the surfaces thereof.

Here, the first gate insulating layer 41 of the organic TFT 4 is formed to have a greater surface energy than the second gate insulating layer 42. In this regard, the first gate insulating layer 41 of the organic TFT 4 is different from the first gate insulating layer 31 of the organic TFT 3, which was formed to have a lower surface energy than the second gate insulating layer 32.

A material that has a higher surface energy than the material used for the second gate insulating layer 42 may be used as the material for the first gate insulating layer 41.

Alternatively, like in Embodiment 3, the first gate insulating layer 41 may be formed using the same material used for the second gate insulating layer 42. In this case, the first gate insulating layer 41 may be formed having a greater surface energy than the second gate insulating layer 42 by irradiating the surface of the first gate insulating layer 41 with UV light or by applying a monolayer film such as a silane coupling agent to the surface of the first gate insulating layer 41.

Moreover, the process for applying a surface treatment to the surface of the first gate insulating layer 41 in order to increase the surface energy thereof (a process for irradiating the surface of the first gate insulating layer 41 with UV light or for applying a monolayer film such as a silane coupling agent, for example) may be performed either before or after the processes for forming the source electrode 14 and the drain electrode 15.

(Second Gate Insulating Layer 42)

The second gate insulating layer 42 is formed on top of the first gate insulating layer 41 and fills the space between the source electrode 14 and the drain electrode 15 arranged with a gap therebetween on the first gate insulating layer 41.

Here, the second gate insulating layer 42 of the organic TFT 4 is formed to have a smaller surface energy than the first gate insulating layer 41. In other words, the surface energy ES1 of the first gate insulating layer 41 and the surface energy ES2 of the second gate insulating layer 42 satisfy the relationship ES1>ES2.

In this regard, the second gate insulating layer 42 of the organic TFT 4 is different from the second gate insulating layer 32 of the organic TFT 3, which was formed to have a greater surface energy than the first gate insulating layer 31 (that is, with ES1<ES2).

Similar to the case described above for the second gate insulating layer 32 of the organic TFT 3, a material with a smaller surface energy than the material used for the first gate insulating layer 41 may be used as the material for the second gate insulating layer 42, or the same material used for the first gate insulating layer 41 may be used as the material for the second gate insulating layer 42.

(Effects of Organic TFT 4)

Next, the effects of the organic TFT 4 of the present embodiment will be described with reference to FIG. 10. FIG. 10 is a graph showing the relationship between the water contact angle of a gate insulating film (horizontal axis) and the carrier mobility of an organic semiconductor for an organic TFT (vertical axis) in several typical organic TFTs.

The graph in FIG. 10 is disclosed in Non-Patent Document 4 and shows data for various gate insulating film materials in bottom-gate, bottom-contact organic TFTs. The gate insulating films represented in FIG. 10 were formed using self-assembled monolayers (SAM).

As shown in FIG. 10, the carrier mobility of an organic semiconductor tends to increase as the water contact angle of the gate insulating film in the corresponding organic TFT increases. This, in turn, implies that the carrier mobility of an organic semiconductor should tend to increase as the surface energy of the gate insulating film in the corresponding organic TFT decreases.

In other words, the carrier mobility of an organic semiconductor can be increased by decreasing the surface energy of the gate insulating film contacting that organic semiconductor.

In the organic TFT 4, the second gate insulating layer 42 that contacts the organic semiconductor layer 16 is formed using a low surface energy material, thereby making it possible to increase the carrier mobility of the organic semiconductor layer 16. This, in turn, makes it possible to improve the performance of the organic TFT 4.

Therefore, unlike when using the inkjet 190 of Embodiment 3, the organic TFT 4 of Embodiment 4 can be easily formed even when using a device that does not require high positioning precision to form the organic semiconductor layer 16 (such as when using a spin coating device to form a semiconductor film on the top surface of the second gate insulating layer 42 as the organic semiconductor layer 16). This makes it possible to produce a device with excellent performance.

### Embodiment 5

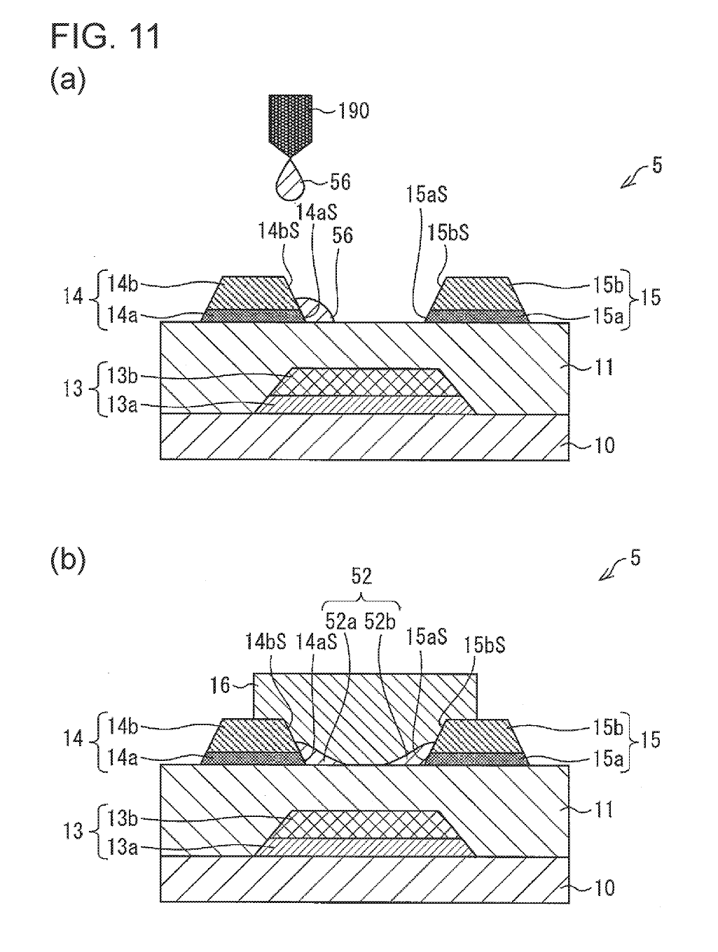

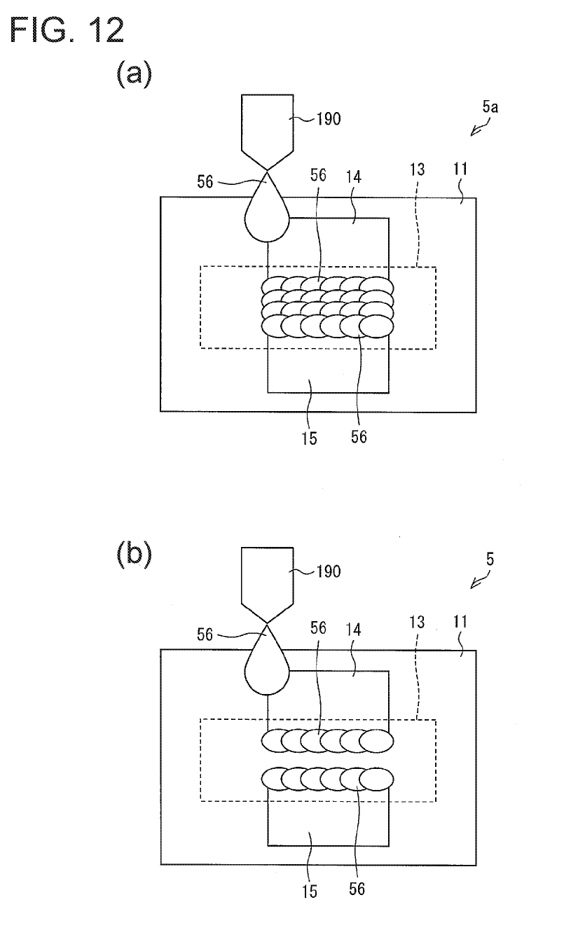

Next, another embodiment of the present invention will be described with reference to FIGS. 11 and 12. For convenience, the same reference characters are used for components that have the same functions as components described in the previous embodiments, and descriptions of those components will be omitted here.

(Configuration of Organic TFT 5)

Next, the configuration of an organic TFT 5 (a semiconductor element) according to the present embodiment will be described with reference to FIGS. 11(a) and 11(b).

FIG. 11(b) is a cross-sectional view of the organic TFT 5. The organic TFT 5 includes a substrate 10, a first gate insulating layer 11, a second gate insulating layer 52, a gate electrode 13, a source electrode 14, a drain electrode 15, and an organic semiconductor layer 16.

Here, except for the second gate insulating layer 52, the components of the organic TFT 5 of Embodiment 5 are the same as the components of the organic TFT 1 of Embodiment 1, and therefore the same reference characters are used for these components that are the same.

The second gate insulating layer 52 includes a source-side second gate insulating layer 52a and a drain-side second gate insulating layer 52b.

FIG. 11(a) illustrates a process for dripping an insulating material 56 between the source electrode 14 and the drain electrode 15 using an inkjet 190 in order to form the second gate insulating layer 52 (this process corresponds to the sixth step (step (f1)) in Embodiment 1). As illustrated in FIG. 11(a), the insulating material 56 is dripped to form the source-side second gate insulating layer 52a.

(Second Gate Insulating Layer 52)

The second gate insulating layer 52 is formed on top of the first gate insulating layer 11 in the space between the source electrode 14 and the drain electrode 15 arranged with a gap therebetween on the first gate insulating layer 11. Furthermore, the second gate insulating layer 52 includes the source-side second gate insulating layer 52a and the drain-side second gate insulating layer 52b.

The source-side second gate insulating layer 52a contacts the source electrode 14, completely covering the first source electrode layer side face 14aS and partially covering the second source electrode layer side face 14bS.

The drain-side second gate insulating layer 52b contacts the drain electrode 15, completely covering the first drain electrode layer side face 15aS and partially covering the second drain electrode layer side face 15bS.

Moreover, the source-side second gate insulating layer 52a and the drain-side second gate insulating layer 52b are formed with a gap therebetween. In other words, the source-side second gate insulating layer 52a and the drain-side second gate insulating layer 52b do not contact one another.

Therefore, the second gate insulating layer 52 of the organic TFT 5 does not completely fill the space between the source electrode 14 and the drain electrode 15. In this regard, the second gate insulating layer 52 of the present embodiment is different from the second gate insulating layers 12, 22, 32, and 42 of Embodiments 1 to 4, which do completely fill the space between the source electrode 14 and the drain electrode 15.

As a result, in the organic TFT 5, the organic semiconductor layer 16 is formed also filling the space between the source-side second gate insulating layer 52a and the drain-side second gate insulating layer 52b.

(Effects of Organic TFT 5)

Next, the effects of the organic TFT 5 of the present embodiment will be described with reference to FIG. 12(b). FIG. 12(b) illustrates a process for dripping the insulating material 56 using the inkjet 190 in order to partially fill the space between the source electrode 14 and the drain electrode 15 in the organic TFT 5a (this process corresponds to the sixth step in Embodiment 1).

First, however, consider the organic TFT 5a illustrated in FIG. 12(a). The organic TFT 5a is the same as the organic TFT according to any one of Embodiments 1 to 4 as described above. Here, the organic TFT 5a is the same as the organic TFT 1 of Embodiment 1, for example. The components of the organic TFT 5a are the same as the components of the organic TFT 1 of Embodiment 1, and therefore the same reference characters are used for these components.

FIG. 12(a) illustrates a process for dripping the insulating material 56 using the inkjet 190 in order to completely fill the space between the source electrode 14 and the drain electrode 15 in the organic TFT 5a (this process corresponds to the sixth step (step (f1)) in Embodiment 1).

In the organic TFT 5a, the insulating material 56 is dripped from the inkjet 190 onto the top surface of the first gate insulating layer 11 and completely fills the space between the source electrode 14 and the drain electrode 15.

The second gate insulating layer 12 of the organic TFT 5a is formed from the insulating material 56 and is therefore formed completely filling the space between the source electrode 14 and the drain electrode 15.

In the organic TFT 5a, the inkjet 190 drips multiple drops of the insulating material 56 such that the insulating material 56 completely fills the space between the source electrode 14 and the drain electrode 15.

Meanwhile, as illustrated in FIG. 12, in the organic TFT 5 of the present embodiment the insulating material 56 is dripped from the inkjet 190 onto the top surface of the first gate insulating layer 11 with some of the insulating material 56 contacting the source electrode 14 and some of the insulating material 56 contacting the drain electrode.

Here, the drops of the insulating material 56 dripped onto the first gate insulating layer 11 contacting the source electrode 14 are separated from and do not contact the drops of the insulating material 56 dripped onto the first gate insulating layer 11 contacting the drain electrode 15.

The drops of the insulating material 56 dripped onto the first gate insulating layer 11 contacting the source electrode 14 form the source-side second gate insulating layer 52a that contacts the source electrode 14. Similarly, the drops of the insulating material 56 dripped onto the first gate insulating layer 11 contacting the drain electrode 15 form the drain-side second gate insulating layer 52b that contacts the drain electrode 15.

Therefore, in the second gate insulating layer 52 of the organic TFT 5, the source-side second gate insulating layer 52a and the drain-side second gate insulating layer 52b do not contact one another.

The second gate insulating layer 52 of the organic TFT 5 is formed by dripping some of the insulating material 56 to be in contact with the source electrode 14 and dripping some of the insulating material 56 to be in contact with the drain electrode 15. Therefore, the second gate insulating layer 52 of the organic TFT 5 is formed using fewer drops of the insulating material 56 than in the second gate insulating layer 12 of the organic TFT 5a.

As a result, in the organic TFT 5 the only insulating layer covering the center region of the channel in the organic semiconductor layer 16 is the first gate insulating layer 11, which has a uniform film thickness. In the organic TFT 5, the second gate insulating layer 52 does not cover the center region of the channel in the organic semiconductor layer 16, and therefore any negative effects on the performance of the organic TFT 5 due to non-uniformity in the film thickness of the second gate insulating layer 52 are small.

Therefore, the second gate insulating layer 52 does not necessarily have to be formed with a perfectly uniform film thickness in order to be able to reduce variations or the like in the performance of the organic TFT 5. This makes it possible to achieve reduced variation in the performance of the organic TFT 5.

### Embodiment 6

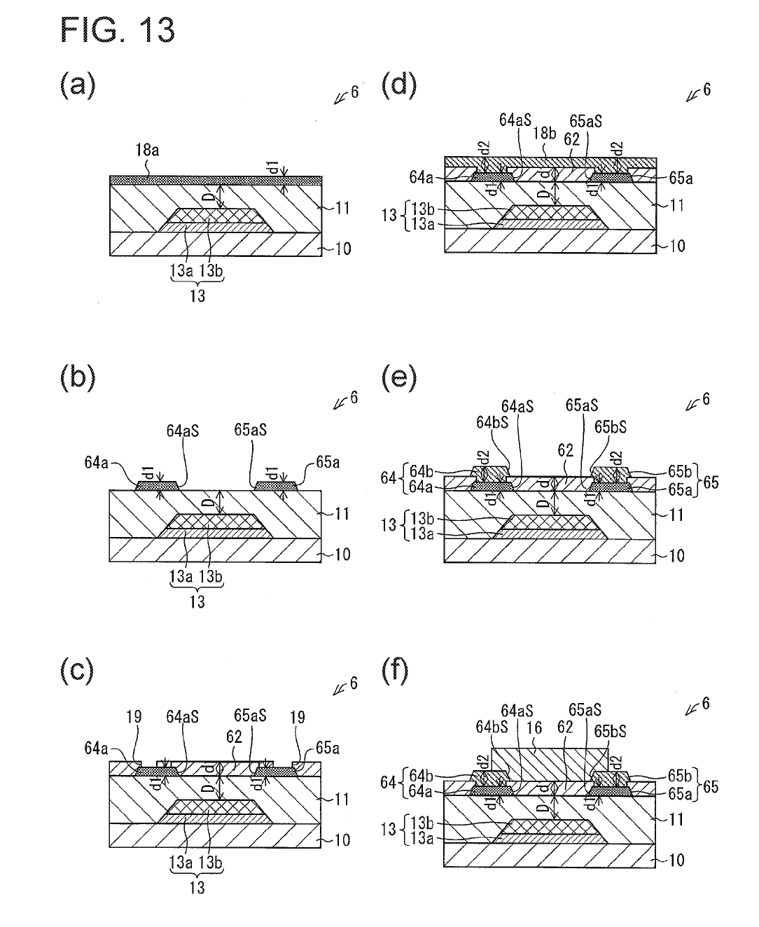

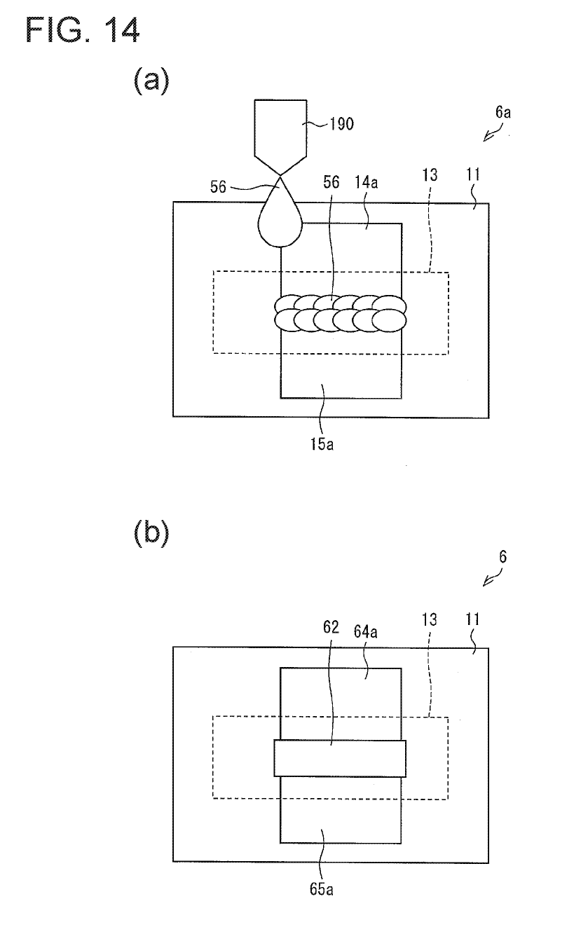

Next, another embodiment of the present invention will be described with reference to FIGS. 13 and 14. For convenience, the same reference characters are used for components that have the same functions as components described in the previous embodiments, and descriptions of those components will be omitted here.

(Configuration of Organic TFT 6)

Next, the configuration of an organic TFT 6 (a semiconductor element) according to the present embodiment will be described with reference to FIG. 13(f). FIG. 13(f) is a cross-sectional view illustrating the organic TFT 6 in a completed state after forming the organic semiconductor layer 16. The organic TFT 6 includes a substrate 10, a first gate insulating layer 11, a second gate insulating layer 62, a gate electrode 13, a source electrode 64, a drain electrode 65, and an organic semiconductor layer 16.

Here, except for the second gate insulating layer 62, the source electrode 64, and the drain electrode 65, the components of the organic TFT 6 of Embodiment 6 are the same as the components of the organic TFT 1 of Embodiment 1, and therefore the same reference characters are used for these components that are the same.

(Method and Steps for Manufacturing Organic TFT)

Next, a method for manufacturing the organic TFT 6 according to the present embodiment as well as the manufacturing steps therein will be described with reference to FIGS. 13(a) to 13(f). FIGS. 13(a) to 13(f) are cross-sectional views of the organic TFT 6 illustrating each step of the method for manufacturing the organic TFT 6.

(First Step in Embodiment 6: Form Base Material Film for First Source/Drain Electrode Layer)

As illustrated in FIG. 13(a), before forming a first source electrode layer 64a for the source electrode 64 and a first drain electrode layer 65a for the drain electrode 65, a first source/drain electrode layer base material 18a is formed as a film over the entire top surface of the first gate insulating layer 11 (first step in Embodiment 6, step (d2)).

The first step in Embodiment 6 is equivalent to the step after the third step in Embodiment 1 (see FIG. 2(c)). In other words, before the first step in Embodiment 6, the first gate insulating layer 11 and the gate electrode 13 of the organic TFT 6 are formed on the substrate 10 the same as in the first step (step (a1)) to the third step (step (c1)) in Embodiment 1.

In Embodiment 6, PMMA is selected as the material for the first gate insulating layer 11. The first gate insulating layer 11 is formed as a PMMA film with a film thickness D=500 nm using a spin coating device.

Moreover, in the gate electrode 13, Cr is selected as the material for the first gate electrode layer 13a, and Al is selected as the material for the second gate electrode layer 13b. The first gate electrode layer 13a that functions as an adhesion layer is formed with a film thickness of 5 nm, and the second gate electrode layer 13b that functions as a contact layer is formed with a film thickness of 300 nm.

In the first step of Embodiment 6, a layer of a material that functions as an adhesion layer is formed over the entire top surface of the first gate insulating layer 11 like in the fourth step in Embodiment 1 (see FIG. 2(d)) using a spin coating device in order to form the first source/drain electrode layer base material 18a. Here, Cr is selected as the material for the first source/drain electrode layer base material 18a, and the first source/drain electrode layer base material 18a is formed as a film with a thickness d1=5 nm.

(Second Step in Embodiment 6: Form First Source Electrode Layer and First Drain Electrode Layer)

As illustrated in FIG. 13(b), the first source electrode layer 64a and the first drain electrode layer 65a are formed from the first source/drain electrode layer base material 18a (second step in Embodiment 6, step (e2)).

In the second step in Embodiment 6, like in the fifth step (see FIG. 2(e)) in Embodiment 1, a photolithography process is applied to the first source/drain electrode layer base material 18a covering the entire top surface of the first gate insulating layer 11 to remove the unnecessary portions of the first source/drain electrode layer base material 18a, thereby forming the first source electrode layer 64a and the first drain electrode layer 65a.

In this way, the first source electrode layer 64a and the first drain electrode layer 65a are formed with a gap therebetween on top of the first gate insulating layer 11. Note that the film thickness d1 of the first source electrode layer 64a and the first drain electrode layer 65a are equal to the film thickness of the first source/drain electrode layer base material 18a, with d1=5 nm.

The side face of the first source electrode layer 64a facing the first drain electrode layer 64b will be referred to as the first source electrode layer side face 64aS. Similarly, the side face of the first drain electrode layer 65a facing the first source electrode layer 64a will be referred to as the first drain electrode layer side face 65aS.

(Third Step in Embodiment 6: Form Second Gate Insulating Layer)

As illustrated in FIG. 13(c), the second gate insulating layer 62 is formed on top of the first gate insulating layer 11 in the space between the first source electrode layer 64a and the first drain electrode layer 65a arranged with a gap therebetween on the first gate insulating layer 11 (third step in Embodiment 6, step (f2)).

In the third step in Embodiment 6, a film of an insulating material is formed over the entire top surfaces of the first gate insulating layer 11, the first source electrode layer 64a, and the first drain electrode layer 65a using a spin coating device. CYTOP is selected for this insulating material, and the film of the insulating material is formed with a film thickness d=10 nm.

Next, a photolithography process is applied to remove the film of the insulating material on the top surfaces of the first source electrode layer 64a and the first drain electrode layer 65a to form openings 19 thereover.

In this way, the second gate insulating layer 62 is formed in the space between first source electrode layer 64a and the first drain electrode layer 65a. Furthermore, the second gate insulating layer 62 includes the openings 19. The film thickness d of the second gate insulating layer 62 is equal to the film thickness of the insulating material formed prior to the photolithography process, with d=10 nm.

The second gate insulating layer 62 may be formed in any manner as long as the second gate insulating layer 62 completely covers the first source electrode layer side face 64aS and the first drain electrode layer side face 65aS. Therefore, the entire second gate insulating layer 62 does not need to be formed such that the relationship d1<d is satisfied.

For example, the second gate insulating layer 62 may be formed such that the portions thereof that contact the first source electrode layer 64a and the first drain electrode layer 65a have a film thickness greater than d1 and such that the portions of the second gate insulating layer 62 that do not contact the first source electrode layer 64a and the first drain electrode layer 65a (such as the portions near the center of the second gate insulating layer 62) have a film thickness less than d1 by forming fewer layers of the insulating material for those portions. In this way, the second gate insulating layer 62 of the present embodiment exhibits the same effects as the second gate insulating layer 52 of Embodiment 5.

(Fourth Step in Embodiment 6: Form Base Material Film for Second Source/Drain Electrode Layer)

As illustrated in FIG. 13(d), before forming a second source electrode layer 64b of the source electrode 64 and a second drain electrode layer 65b of the drain electrode 65, a second source/drain electrode layer base material 18b is formed as a film over the entire top surface of the second gate insulating layer 62 (fourth step in Embodiment 6, step (g2)).

In the fourth step of Embodiment 6, a layer of a material that functions as a contact layer is formed over the entire top surfaces of the second gate insulating layer 62, the first source electrode layer 64a, and the first drain electrode layer 65a like in the fourth step in Embodiment 1 (see FIG. 2(d)) using a spin coating device in order to form the second source/drain electrode layer base material 18b.

Here, Au is selected as the material for the second source/drain electrode layer base material 18b. Furthermore, the second source/drain electrode layer base material 18b is formed as a film with a film thickness d2=50 nm at the positions where the openings 19 are formed over the first source electrode layer 64a and the first drain electrode layer 65a.

(Fifth Step in Embodiment 6: Form Source Electrode and Drain Electrode)

As illustrated in FIG. 13(e), the second source electrode layer 64b and the second drain electrode layer 65b are formed from the second source/drain electrode layer base material 18b in order to form the source electrode 64 and the drain electrode 65 (fifth step in Embodiment 6, step (h2)).

In the fifth step in Embodiment 6, like in the fifth step (see FIG. 2(e)) in Embodiment 1, a photolithography process is applied to the second source/drain electrode layer base material 18b to remove the portions of the second source/drain electrode layer base material 18b at positions not corresponding to where the openings 19 are formed over the first source electrode layer 64a and the first drain electrode layer 65a.

Furthermore, two portions of the second source/drain electrode layer base material 18b are left remaining on top of the first source electrode layer 64a and the first drain electrode layer 65a and face one another. These remaining portions of the second source/drain electrode layer base material 18b are the second source electrode layer 64b and the second drain electrode layer 65b.

The side face of the second source electrode layer 64b facing the second drain electrode layer 65b will be referred to as the second source electrode layer side face 64bS. Similarly, the side face of the second drain electrode layer 65b facing the second source electrode layer 64b will be referred to as the second drain electrode layer side face 65bS.

In this way, the source electrode 64 that includes the first source electrode layer 64a and the second source electrode layer 64b and the drain electrode 65 that includes the first drain electrode layer 65a and the second drain electrode layer 65b are formed with a gap therebetween. Moreover, the film thickness of the second source electrode layer 64b and the second drain electrode layer 65b is d2=50 nm.

(Sixth Step in Embodiment 6: Form Organic Semiconductor Layer)

As illustrated in FIG. 13(f), the organic semiconductor layer 16 is formed on top of the second gate insulating layer 62, the source electrode 64, and the drain electrode 65 such that the organic semiconductor layer 16 completely covers the surface of the second gate insulating layer 62 and partially covers the surfaces of the source electrode 64 and the drain electrode 65 (sixth step in Embodiment 6).

The sixth step in Embodiment 6 corresponds to the seventh step (see FIG. 2(g)) in Embodiment 1, and like in that seventh step (step(g1)) in Embodiment 1, the organic semiconductor layer 16 is formed to complete the organic TFT 6 of the present embodiment.

The organic TFT 6 of the present embodiment is formed using the first to sixth manufacturing steps described above and illustrated in FIGS. 13(a) to 13(f).

(Effects of Organic TFT 6)

Next, the effects of the organic TFT 6 of the present embodiment will be described with reference to FIG. 14(b). FIG. 14(b) illustrates a process for forming the second gate insulating layer 62 between the first source electrode layer 64a and the second drain electrode layer 65a using a spin coating device (this process corresponds to the third step in Embodiment 6).

First, however, consider the organic TFT 6a illustrated in FIG. 14(a). The organic TFT 6a is the same as the organic TFT according to any one of Embodiments 1 to 5 as described above. Here, the organic TFT 6a is the same as the organic TFT 1 of Embodiment 1, for example. Here, the components of the organic TFT 6a are the same as the components of the organic TFT 1 of Embodiment 1, and therefore the same reference characters are used for these components.

FIG. 14(a) illustrates a process for forming a second gate insulating layer by using an inkjet 190 to drip an insulating material 56 (this process corresponds to the third step in Embodiment 6).

FIG. 14(a) corresponds to FIG. 12(a) of the organic TFT 5a. Like in the organic TFT 5a, in the organic TFT 6a illustrated in FIG. 14(a), the inkjet 190 drips multiple drops of the insulating material 56 such that the insulating material 56 completely fills the space between the first source electrode layer 14a and the first drain electrode layer 15a.

Meanwhile, in the organic TFT 6 of the present embodiment as illustrated in FIG. 14(b), the second gate insulating layer 62 is formed using a spin coating device and photolithography as described in the third step in Embodiment 6.

Therefore, the second gate insulating layer 62 of the organic TFT 6 is formed with greater uniformity in film thickness than the second gate insulating layer of the organic TFT 6a. This makes it possible to achieve reduced variation in the performance of the organic TFT 6.

### Embodiment 7

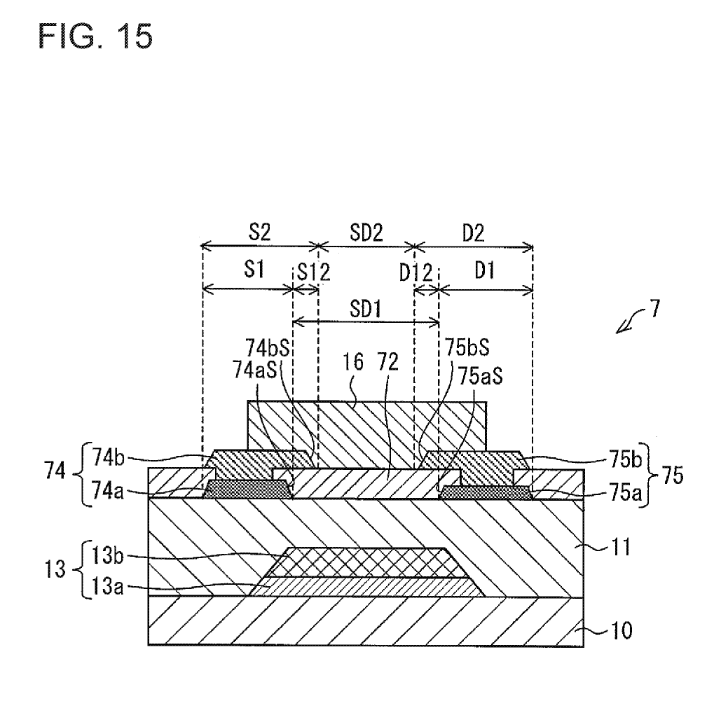

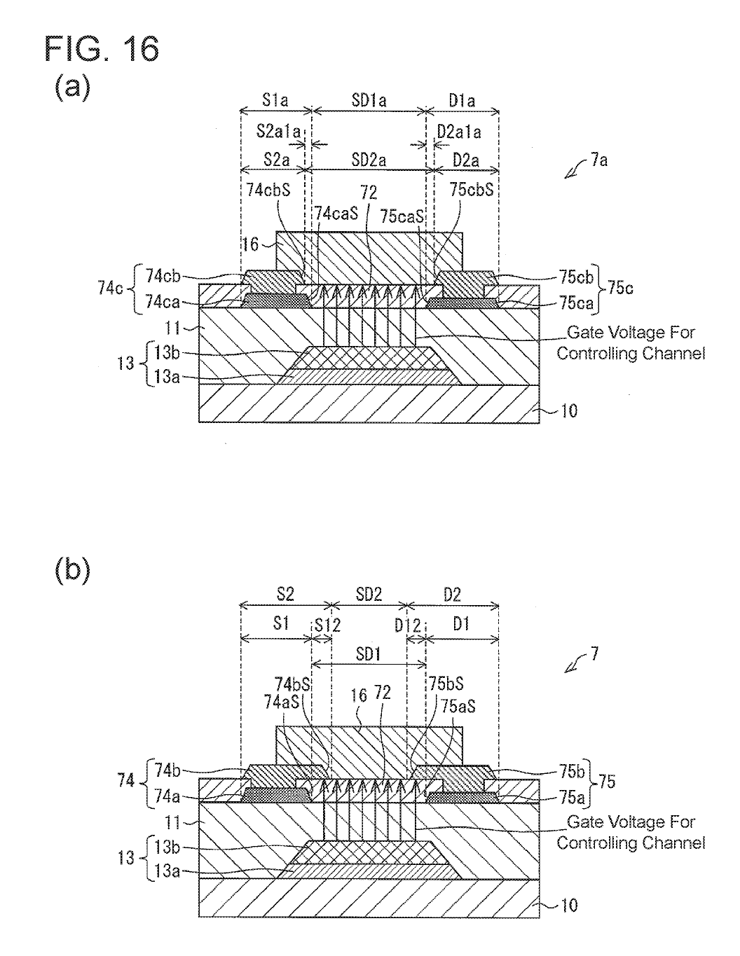

Next, another embodiment of the present invention will be described with reference to FIGS. 15 and 16. For convenience, the same reference characters are used for components that have the same functions as components described in the previous embodiments, and descriptions of those components will be omitted here.

(Configuration of Organic TFT 7)

Next, the configuration of an organic TFT 7 (a semiconductor element) according to the present embodiment will be described with reference to FIG. 15. FIG. 15 is a cross-sectional view of the organic TFT 7. The organic TFT 7 includes a substrate 10, a first gate insulating layer 11, a second gate insulating layer 72, a gate electrode 13, a source electrode 74, a drain electrode 75, and an organic semiconductor layer 16.

Here, except for the second gate insulating layer 72, the source electrode 74, and the drain electrode 75, the components of the organic TFT 7 of Embodiment 7 are the same as the components of the organic TFT 1 of Embodiment 1, and therefore the same reference characters are used for these components that are the same.

Moreover, the second gate insulating layer 72 of the organic TFT 7 is the same as the second gate insulating layer 62 of the organic TFT 6 of Embodiment 6. Next, the source electrode 74 and the drain electrode 75 of the present embodiment will be described.

(Source Electrode 74)

The source electrode 74 is formed the same as in the fifth step (see FIG. 13(e)) of Embodiment 6 and includes a first source electrode layer 74a that functions as an adhesion layer and a second source electrode layer 74b that functions as a contact layer.

The side face of the first source electrode layer 74a facing a first drain electrode layer 75a will be referred to as the first source electrode layer side face 74aS. Similarly, the side face of the first drain electrode layer 75a facing the first source electrode layer 74a will be referred to as the first drain electrode layer side face 75aS.

The side face of the second source electrode layer 74b facing a second drain electrode layer 75b will be referred to as the second source electrode layer side face 74bS. Similarly, the side face of the second drain electrode layer 75b facing the second source electrode layer 74b will be referred to as the second drain electrode layer side face 75bS.

Here, in the source electrode 74, let the distance from the edge of the first source electrode layer side face 74aS to the edge of the side face opposite to the first source electrode layer side face 74aS be S1. Similarly, in the source electrode 74, let the distance from the edge of the second source electrode layer side face 74bS to the edge of the side face opposite to the second source electrode layer side face 74bS be S2.

Below, the direction in which the source electrode 74 and the drain electrode 75 face one another will be referred to as the horizontal direction. Furthermore, FIG. 15 depicts an example in which the edge of the side face opposite to the first source electrode layer side face 74aS and the edge of the side face opposite to the second source electrode layer side face 74bS are aligned in the horizontal direction.

In the source electrode 74, the first source electrode layer 74a and the second source electrode layer 74b are formed such that the following relationship holds between S1 and S2:

S2>S1 (3)

Therefore, from formula (3), the distance S12 from the edge of the first source electrode layer side face 74aS to the edge of the second source electrode layer side face 74bS is:

S12=S2−S1>0 (4)

As indicated in formula (4), S12>0, and therefore the edge of the second source electrode layer side face 74bS is positioned closer to the drain electrode 75 than is the edge of the first source electrode layer side face 74aS. Therefore, the edge of the second source electrode layer side face 74bS extends deeper into the organic semiconductor layer 16 than does the edge of the first source electrode layer side face 74aS.

(Drain Electrode 75)

The drain electrode 75 is formed the same as in the fifth step (see FIG. 13(e)) of Embodiment 6 and includes the first drain electrode layer 75a that functions as an adhesion layer and the second drain electrode layer 75b that functions as a contact layer.

Here, in the drain electrode 75, let the distance from the edge of the first drain electrode layer side face 75aS to the edge of the side face opposite to the first drain electrode layer side face 75aS be D1. Similarly, in the drain electrode 75, let the distance from the edge of the second drain electrode layer side face 75bS to the edge of the side face opposite to the second drain electrode layer side face 75bS be D2.

FIG. 15 depicts an example in which the edge of the side face opposite to the first drain electrode layer side face 75aS and the edge of the side face opposite to the second drain electrode layer side face 75bS are aligned in the horizontal direction.

In the drain electrode 75, the first drain electrode layer 75a and the second drain electrode layer 75b are formed such that the following relationship holds between D1 and D2:

D2>D1 (5)

Therefore, from formula (5), the distance D12 from the edge of the first drain electrode layer side face 75aS to the edge of the second drain electrode layer side face 75bS is:

D12=D2−D1>0 (6)

As indicated in formula (6), D12>0, and therefore the edge of the second drain electrode layer side face 75bS is positioned closer to the source electrode 74 than is the edge of the first drain electrode layer side face 75aS. Therefore, the edge of the second drain electrode layer side face 75bS extends deeper into the organic semiconductor layer 16 than does the edge of the first drain electrode layer side face 75aS.

Next, let the distance in the horizontal direction between the first source electrode layer side face 74aS and the first drain electrode layer side face 75aS be SD1, and let the distance in the horizontal direction between the second source electrode layer side face 74bS and the second drain electrode layer side face 75bS be SD2.

Here, SD1 and SD2 satisfy the following relationship:

SD2=SD1−(S12+D12) (7)

Also, from formulas (4) and (6):

SD2<SD1 (8)

In other words, the distance SD2 in the horizontal direction between the second source electrode layer side face 74bS and the second drain electrode layer side face 75bS is less than the distance SD1 in the horizontal direction between the first source electrode layer side face 74 aS and the first drain electrode layer side face 75aS.

(Effects of Organic TFT 7)

Next, the effects of the organic TFT 7 of the present embodiment will be described with reference to FIG. 16(b). FIG. 16(b) is a cross-sectional view of the organic TFT 7 according to the present embodiment illustrating a gate voltage for controlling the channel in the organic semiconductor layer 16 of the organic TFT 7 being applied from the second gate electrode layer 13b of the gate electrode 13.

First, however, consider the organic TFT 7a illustrated in FIG. 16(a). The organic TFT 7a is the same as the organic TFT according to any one of Embodiments 1 to 6 as described above. FIG. 16(a) is a cross-sectional view of the organic TFT 7a illustrating a gate voltage for controlling the channel in the organic semiconductor layer 16 of the organic TFT 7a being applied from the second gate electrode layer 13b of the gate electrode 13.

The organic TFT 7a includes a second gate insulating layer 72, a source electrode 74c, and a drain electrode 75c. The source electrode 74c includes a first source electrode layer 74ca and a second source electrode layer 74cb. Similarly, the drain electrode 75c includes a first drain electrode layer 75ca and a second drain electrode layer 75cb.

The side face of the first source electrode layer 74ca facing the first drain electrode layer 75ca will be referred to as the first source electrode layer side face 74caS. Similarly, the side face of the first drain electrode layer 75ca facing the first source electrode layer 74ca will be referred to as the first drain electrode layer side face 75caS.

The side face of the second source electrode layer 74cb facing the second drain electrode layer 75b will be referred to as the second source electrode layer side face 74cbS. Similarly, the side face of the second drain electrode layer 75cb facing the second source electrode layer 74cb will be referred to as the second drain electrode layer side face 75cbS.

Here, in the source electrode 74c, let the distance from the edge of the first source electrode layer side face 74caS to the edge of the side face opposite to the first source electrode layer side face 74caS be S1a. Similarly, in the source electrode 74c, let the distance from the edge of the second source electrode layer side face 74cbS to the edge of the side face opposite to the second source electrode layer side face 74cbS be S2a.

FIG. 16(a) depicts an example in which the edge of the side face opposite to the first source electrode layer side face 74caS and the edge of the side face opposite to the second source electrode layer side face 74cbS are aligned in the horizontal direction.

In the source electrode 74c, the first source electrode layer 74ca and the second source electrode layer 74cb are formed such that the following relationship holds between S1a and S2a:

S1a>S2a (9)

Therefore, from formula (9), the distance S2a1a from the edge of the first source electrode layer side face 74caS to the edge of the second source electrode layer side face 74cbS is:

S2a1a=S1a−S2a>0 (10)

As indicated in formula (10), S2a1a>0, and therefore the edge of the second source electrode layer side face 74cbS is positioned farther away from the drain electrode 75c than is the edge of the first source electrode layer side face 74caS. Therefore, the edge of the second source electrode layer side face 7c4bS extends less deeply into the organic semiconductor layer 16 than does the edge of the first source electrode layer side face 74caS.

In the drain electrode 75c, let the distance from the edge of the first drain electrode layer side face 75caS to the edge of the side face opposite to the first drain electrode layer side face 75caS be D1a. Similarly, in the drain electrode 75c, let the distance from the edge of the second drain electrode layer side face 75cbS to the edge of the side face opposite to the second drain electrode layer side face 75cbS be D2a.

FIG. 16(a) depicts an example in which the edge of the side face opposite to the first drain electrode layer side face 75caS and the edge of the side face opposite to the second drain electrode layer side face 75cbS are aligned in the horizontal direction.

In the drain electrode 75c, the first drain electrode layer 75ca and the second drain electrode layer 75cb are formed such that the following relationship holds between D1a and D2a:

D1a>D2a (11)

Therefore, from formula (11), the distance D2a1a from the edge of the first drain electrode layer side face 75caS to the edge of the second drain electrode layer side face 75cbS is:

D2a1a=D1a−D2a>0 (12)

As indicated in formula (12), D2a1a>0, and therefore the edge of the second drain electrode layer side face 75cbS is positioned further away from the source electrode 74c than is the edge of the first drain electrode layer side face 75caS. Therefore, the edge of the second drain electrode layer side face 75cbS extends less deeply into the organic semiconductor layer 16 than does the edge of the first drain electrode layer side face 75caS.

Next, let the distance in the horizontal direction between the first source electrode layer side face 74caS and the first drain electrode layer side face 75caS be SD1a, and let the distance in the horizontal direction between the second source electrode layer side face 74cbS and the second drain electrode layer side face 75cbS be SD2a.

Here, SD1a and SD2a satisfy the following relationship:

SD2a=SD1a+(S2a1a+D2a1a) (13)

Also, from formulas (10) and (12):

SD2a>SD1a (14)

In other words, the distance SD2a in the horizontal direction between the second source electrode layer side face 74cbS and the second drain electrode layer side face 75cbS is greater than the distance SD1a in the horizontal direction between the first source electrode layer side face 74caS and the first drain electrode layer side face 75caS.

As illustrated in FIG. 16(a), in the organic semiconductor layer 16, a gate voltage is applied from the second gate electrode layer 13b to the channel formed in the region between the second source electrode layer side face 74cbS and the second drain electrode layer side face 75cbS. This gate voltage controls the channel in the organic semiconductor layer 16 as well as the output characteristics of the organic TFT 7a.

As indicated in formula (14), in the organic TFT 7a, the edge of the second source electrode layer side face 74cbS extends less deeply into the organic semiconductor layer 16 than does the edge of the first source electrode layer side face 74caS, and the edge of the second drain electrode layer side face 75cbS extends less deeply into the organic semiconductor layer 16 than does the edge of the first drain electrode layer side face 75caS.

As a result, the gate voltage applied to the channel in the organic semiconductor layer 16 from the second gate electrode layer 13b is blocked by the edge of the first source electrode layer side face 74caS and the edge of the first drain electrode layer side face 75caS, which extend more deeply into the organic semiconductor layer 16.

Meanwhile, the channel in the organic semiconductor layer 16 is formed between the edge of the second source electrode layer side face 74cbS and the edge of the second drain electrode layer side face 75cbS, which extend less deeply into the organic semiconductor layer 16.

Therefore, the overall width of the channel formed in the organic semiconductor layer 16 is greater than the width to which the gate voltage can actually be applied from the second gate electrode layer 13b.

Meanwhile, in the organic TFT 7 of the present embodiment as illustrated in FIG. 16(b), in the organic semiconductor layer 16, a gate voltage is applied from the second gate electrode layer 13b to the channel formed in the region between the second source electrode layer side face 74bS and the second drain electrode layer side face 75bS. This gate voltage controls the channel in the organic semiconductor layer 16 as well as the output characteristics of the organic TFT 7.

As indicated in formula (8), in the organic TFT 7, the edge of the second source electrode layer side face 74bS extends deeper into the organic semiconductor layer 16 than does the edge of the first source electrode layer side face 74aS, and the edge of the second drain electrode layer side face 75bS extends deeper into the organic semiconductor layer 16 than does the edge of the first drain electrode layer side face 75aS.

As a result, the gate voltage applied to the channel in the organic semiconductor layer 16 from the second gate electrode layer 13b is blocked by the edge of the second source electrode layer side face 74bS and the edge of the second drain electrode layer side face 75bS, which extend more deeply into the organic semiconductor layer 16.

Furthermore, the channel in the organic semiconductor layer 16 is formed between the edge of the second source electrode layer side face 74bS and the edge of the second drain electrode layer side face 75bS, which extend more deeply into the organic semiconductor layer 16.

Therefore, in the organic TFT 7, the gate voltage can appropriately control the entire channel between the second source electrode layer 74cb and the second drain electrode layer 75cb in the organic semiconductor layer 16. Therefore, the organic TFT 7 exhibits improved channel controllability and makes it possible to reduce decreases in output performance.

(Modification Example)

In the organic TFT 7, the source electrode 74 and the drain electrode 75 may also be configured to not include the first source electrode layer 74a and the drain electrode 74b that function as adhesion layers. In other words, the source electrode 74 and the drain electrode 75 may each include a plurality of conductive layers, like in Embodiment 9 below.

The source electrode 74 and the drain electrode 75 may each include two conductive layers, for example.

Here, let the horizontal direction be the direction in which the source electrode and the drain electrode face one another. The side face of the first source electrode layer facing the first drain electrode layer will be referred to as the first source electrode layer side face, and the side face of the first drain electrode layer facing the first source electrode layer will be referred to as the first drain electrode layer side face.

Similarly, the side face of the second source electrode layer facing the second drain electrode layer will be referred to as the second source electrode layer side face, and the side face of the second drain electrode layer facing the second source electrode layer will be referred to as the second drain electrode layer side face.

In this case, the same effects described above can be achieved by making the distance in the horizontal direction between the second source electrode layer side face and the second drain electrode layer side face less than the distance in the horizontal direction between the first source electrode layer side face and the first drain electrode layer side face.

### Embodiment 8

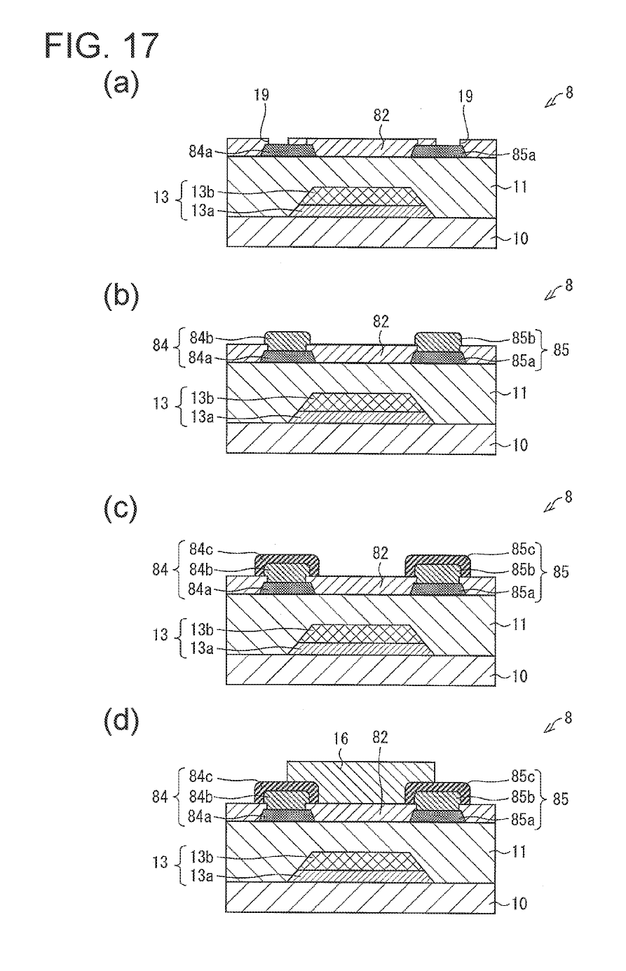

Another embodiment of the present invention will be described below with reference to FIG. 17. For convenience, the same reference characters are used for components that have the same functions as components described in the previous embodiments, and descriptions of those components will be omitted here.

(Configuration of an Organic TFT 8)

Next, the configuration of an organic TFT 8 (a semiconductor element) according to the present embodiment will be described with reference to FIG. 17(d). FIG. 17(d) is a cross-sectional view illustrating the organic TFT 8 in a completed state after forming the organic semiconductor layer 16. The organic TFT 8 includes a substrate 10, a first gate insulating layer 11, a second gate insulating layer 82, a gate electrode 13, a source electrode 84, a drain electrode 85, and an organic semiconductor layer 16.

Here, except for the second gate insulating layer 82, the source electrode 84, and the drain electrode 85, the components of the organic TFT 8 of Embodiment 8 are the same as the components of the organic TFT 1 of Embodiment 1, and therefore the same reference characters are used for these components that are the same.

The second gate insulating layer 82 of the organic TFT 8 is the same as the second gate insulating layer 72 of the organic TFT 7 of Embodiment 7. Furthermore, the source electrode 84 includes a first source electrode layer 84a, a second source electrode layer 84b (a source electrode intermediate layer), and a third source electrode layer 84c (a second source electrode layer). The drain electrode 85 includes a first drain electrode layer 85a, a second drain electrode layer 85b (a drain electrode intermediate layer), and a third drain electrode layer 85c (a second drain electrode layer).

(Method and Steps for Manufacturing Organic TFT 8)

Next, a method for manufacturing the organic TFT 8 according to the present embodiment as well as the manufacturing steps therein will be described with reference to FIGS. 17(a) to 17(d). FIGS. 17(a) to 17(d) are cross-sectional views of the organic TFT 8 illustrating each step of the method for manufacturing the organic TFT 8.

(First Step in Embodiment 8: Form Second Gate Insulating Layer)

As illustrated in FIG. 17(a), the second gate insulating layer 82 is formed on top of the first gate insulating layer 11 in the space between the first source electrode layer 84a and the first drain electrode layer 85a arranged with a gap therebetween on the first gate insulating layer 11 (first step in Embodiment 8).

The first step in Embodiment 8 is equivalent to the steps up to the third step in Embodiment 6 (see FIG. 13(c)). In other words, in the first step of Embodiment 8, the first gate insulating layer 11, the gate electrode 13, the second gate insulating layer 82, the first source electrode layer 84a, and the first drain electrode layer 85a of the organic TFT 8 are formed on top of the substrate 10 the same as in the steps up to the third step in Embodiment 6. Next, openings 19 are formed over the first source electrode layer 84a and the first drain electrode layer 85a. These openings 19 are part of the second gate insulating layer 82.

(Second Step in Embodiment 8: Form Second Source and Drain Electrode Layers)

As illustrated in FIG. 17(b), the second source electrode layer 84b of the source electrode 84 and the second drain electrode layer 85b of the drain electrode 85 are formed (second step in Embodiment 8).

In the second step of Embodiment 8, the second source electrode layer 84b is formed filling the opening 19 on top of the first source electrode layer 84a using a well-known electroplating technique. Using the same method, the second drain electrode layer 85b is formed filling the opening 19 on top of the first drain electrode layer 85a.

Here, Cu is selected as the material for the second source electrode layer 84b and the second drain electrode layer 85b.

The second source electrode layer 84b and the second drain electrode layer 85b are auxiliary conductive layers formed in order to reduce the amount of material needed to form the third source electrode layer 84c and the third drain electrode layer 85c, which are formed in order to make good contact with the organic semiconductor layer 16.

Therefore, the material for the second source electrode layer 84b and the second drain electrode layer 85b is not limited to Cu, and any conductive material with a lower cost than the material used for the third source electrode layer 84c and the third drain electrode layer 85c may be used.

(Third Step in Embodiment 8: Form Third Source and Drain Electrode Layers)

As illustrated in FIG. 17(c), the third source electrode layer 84c of the source electrode 84 and the third drain electrode layer 85c of the drain electrode 85 are formed (third step in Embodiment 8).

In the third step of Embodiment 8, the third source electrode layer 84c is formed covering the surface of the second source electrode layer 84b using a well-known plating method such as an electroplating technique. Using the same method, the third drain electrode layer 85c is formed covering the surface of the second drain electrode layer 85b.

Here, Au (which makes good contact with the organic semiconductor layer 16) is selected as the material for the third source electrode layer 84c and the third drain electrode layer 85c. Furthermore, in order to reduce the amount of Au used, the third source electrode layer 84c and the third drain electrode layer 85c are formed as thin films thinner than the second source electrode layer 84b and the second drain electrode layer 85b, which are made from Cu.

Therefore, the third step of Embodiment 8 completes formation of the source electrode 84 that includes the first source electrode layer 84a, the second source electrode layer 84b, and the third source electrode layer 84c as well as formation of the drain electrode 85 that includes the first drain electrode layer 85a, the second drain electrode layer 85b, and the third drain electrode layer 85c.

In the organic TFT 8, the layers of the source electrode 84 and the drain electrode 85 adjacent to the uppermost layers of the source electrode 84 and the drain electrode 85 (that is, the layers adjacent to the third source electrode layer 84c and the third drain electrode layer 85c) are formed protruding up from the openings 19 in the second gate insulating layer 82.

Furthermore, the uppermost layers of the source electrode 84 and the drain electrode 85 are formed covering (capping) these portions of the layers adjacent to the uppermost layers of the source electrode 84 and the drain electrode 85 that protrude from the second gate insulating layer 85.

(Fourth Step in Embodiment 8: Form Organic Semiconductor Layer)

As illustrated in FIG. 17(d), the organic semiconductor layer 16 is formed on top of the second gate insulating layer 82, the source electrode 84, and the drain electrode 85 such that the organic semiconductor layer 16 completely covers the surface of the second gate insulating layer 82 and partially covers the surfaces of the source electrode 84 and the drain electrode 85 (fourth step in Embodiment 8).

The fourth step in Embodiment 8 corresponds to the sixth step in Embodiment 6, and like in the sixth step in Embodiment 6 (that is, like in the seventh step (step(g1)) in Embodiment 1), the organic semiconductor layer 16 is formed to complete the organic TFT 8 of the present embodiment.

The organic TFT 8 of the present embodiment is formed using the first to fourth manufacturing steps described above and illustrated in FIGS. 17(a) to 17(d).

In the organic TFT 8 of the present embodiment, the second gate insulating layer 82 partially covers the layers of the source electrode 84 and the drain electrode 85 other than the uppermost layers thereof and includes the openings 19. The openings 19 formed in the second gate insulating layer 82 contact the layers of the source electrode 84 and the drain electrode 85 other than the uppermost layers thereof.

Furthermore, the uppermost layers of the source electrode 84 and the drain electrode 85 are connected via the openings 19 formed in the second gate insulating layer 82 to those layers other than the uppermost layers of the source electrode 84 and the drain electrode 85.

(Effects of Organic TFT 8)

In the organic TFT 8 of the present embodiment, the source electrode 84 that includes the second source electrode layer 84b and the third source electrode layer 84c (which function as conductive layers) as well the drain electrode 85 that includes the second drain electrode layer 85b and the third drain electrode layer 85c (which also function as conductive layers) are formed using a plating method.

Meanwhile, in the organic TFTs of Embodiments 1 to 7, the source electrode and the drain electrode are formed using photolithography.

Using photolithography requires a large number of manufacturing steps such as film formation, applying photoresist, exposure, developing, etching, and removal. In contrast, using a plating method requires much fewer manufacturing steps.

Therefore, manufacturing the organic TFT 8 using a plating method further reduces the required manufacturing time and costs in comparison with the organic TFTs of Embodiments 1 to 7.

Furthermore, in the organic TFT 8 of the present embodiment, the third source electrode layer 84c and the third drain electrode layer 85c (which are made from Au) are formed covering the surfaces of the second source electrode layer 84b and the second drain electrode layer 85b (which are made from Cu). In addition, the third source electrode layer 84c and the third drain electrode layer 85c are formed as thin films thinner than the second source electrode layer 84b and the second drain electrode layer 85b.

Meanwhile, in the photolithography method used in the organic TFTs of Embodiments 1 to 7, it is difficult to form a thin Au film only in prescribed regions, and therefore each Au thin film is typically formed as an electrode in which the entire electrode functions as a contact layer.

Therefore, using a plating method makes it possible to reduce the amount of Au used in comparison with using photolithography.

In other words, manufacturing the organic TFT 8 using a plating method further reduces the required manufacturing costs in comparison with the organic TFTs of Embodiments 1 to 7.

### Embodiment 9

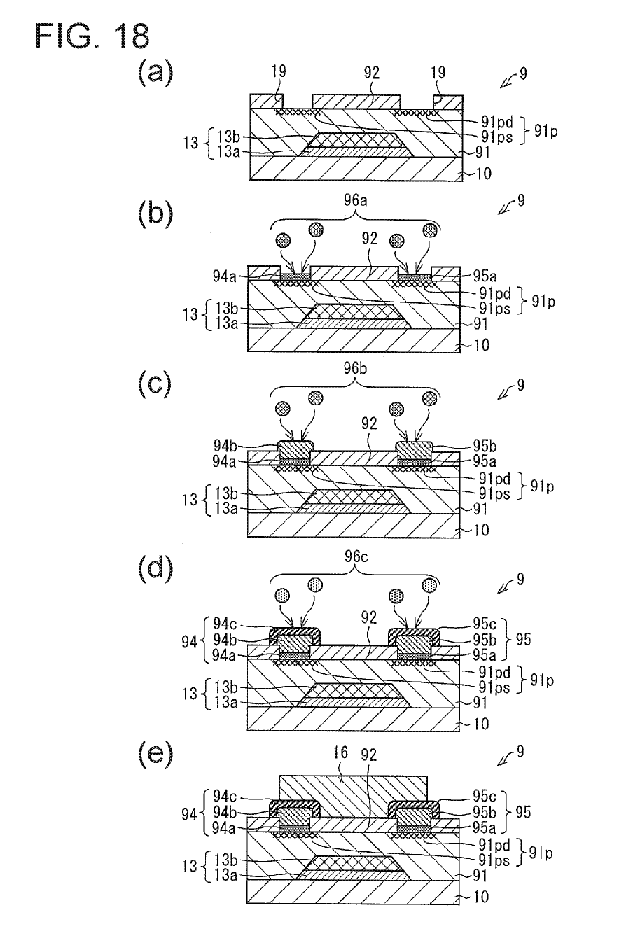

Another embodiment of the present invention will be described below with reference to FIG. 18. For convenience, the same reference characters are used for components that have the same functions as components described in the previous embodiments, and descriptions of those components will be omitted here.

(Configuration of Organic TFT 9)

Next, the configuration of an organic TFT 9 (a semiconductor element) according to the present embodiment will be described with reference to FIG. 18(d). FIG. 19(d) is a cross-sectional view illustrating the organic TFT 9 in a completed state after forming the organic semiconductor layer 16. The organic TFT 9 includes a substrate 10, a first gate insulating layer 91, a second gate insulating layer 92, a gate electrode 13, a source electrode 94, a drain electrode 95, and an organic semiconductor layer 16.

Here, except for the second gate insulating layer 92, the source electrode 94, and the drain electrode 95, the components of the organic TFT 9 of Embodiment 9 are the same as the components of the organic TFT 1 of Embodiment 1, and therefore the same reference characters are used for these components that are the same.

The first gate insulating layer 91 of the organic TFT 9 is the same as the first gate insulating layer 81 of the organic TFT 8 of Embodiment 8. Moreover, the second gate insulating layer 92 of the organic TFT 9 is the same as the second gate insulating layer 82 of the organic TFT 8 of Embodiment 8.

A surface-treated portion 91p that includes a source-side face-treated portion 91ps and a drain-side face-treated portion 91pd is formed in the first gate insulating layer 91.

The source electrode 94 includes a first source electrode layer 94a (a plating layer, an intra-opening plating layer, a first plating layer), a second source electrode layer 94b (a source electrode intermediate layer, a second plating layer), and a third source electrode layer 94c (a surface plating layer). The drain electrode 95 includes a first drain electrode layer 95a (a plating layer, an intra-opening plating layer, a first plating layer), a second drain electrode layer 95b (a drain electrode intermediate layer, a second plating layer), and a third drain electrode layer 95c (a surface plating layer).

In the organic TFT 9, the first source electrode layer 94a is formed on top of the first gate insulating layer 91 at a position corresponding to the source-side face-treated portion 91ps, and the first drain electrode layer 95a is formed on top of the first gate insulating layer 91 at a position corresponding to the drain-side face-treated portion 91pd.

(Method and Steps for Manufacturing Organic TFT 9)

Next, a method for manufacturing the organic TFT 9 according to the present embodiment as well as the manufacturing steps therein will be described with reference to FIGS. 18(a) to 18(e). FIGS. 18(a) to 18(e) are cross-sectional views of the organic TFT 9 illustrating each step of the method for manufacturing the organic TFT 9.

(First Step in Embodiment 9: Apply Surface Treatment to First Gate Insulating Layer)

As illustrated in FIG. 18(a), a surface treatment is applied to the first gate insulating layer 91 to form the surface-treated portion 91p that includes source-side face-treated portion 91ps and the drain-side face-treated portion 91pd (first step in Embodiment 9, step (d3)).

The first step in Embodiment 9 is equivalent to the step after the third step in Embodiment 1 (see FIG. 2(c)).

In other words, before the first step in Embodiment 9, the first gate insulating layer 91 and the gate electrode 13 of the organic TFT 9 are formed on the substrate 10 the same as in the first step (step (a1)) to the third step (step (c1)) in Embodiment 1.

In the first step in Embodiment 9, the second gate insulating layer 92 is formed on top of the first gate insulating layer 91. The second gate insulating layer 92 is patterned to include openings 19 formed on top of the first gate insulating layer 91 at positions corresponding to the source electrode 94 and the drain electrode 95. The second gate insulating layer 92 may be patterned using photolithography or another printing technology.

Next, a surface treatment is applied to the top surface of the first gate insulating layer 91 where exposed by the openings 19 at the positions corresponding to the source electrode 94 and the drain electrode 95 so that a well-known electroless plating technique (such as chemical plating) can be used.

This surface treatment forms the source-side face-treated portion 91ps at the position corresponding to the source electrode 94 and forms the drain-side face-treated portion 91pd at the position corresponding to the drain electrode 95 in the first gate insulating layer 91.

In the present embodiment, a polyimide that contains fine SiO₂ (silica, silicon dioxide) particles is used as the material for the first gate insulating layer 91, and a polyimide that does not contain fine SiO₂ particles is used as the material for the second gate insulating layer 92.

After the second gate insulating layer 92 is patterned, the organic TFT 9 is impregnated with a strongly acidic aqueous solution such as hydrogen flouride (HF) in order to etch the SiO₂ at the surface of the first gate insulating layer 91 and form holes in the surface of the first gate insulating layer 91.

Next, the organic TFT 9 is impregnated with a solution containing palladium to make the palladium enter the holes in the surface of the first gate insulating layer 91. Palladium functions as a catalyst in electroless plating processes and therefore makes it possible to selectively perform electroless plating on the first gate insulating layer 91.

In this way, a surface treatment is applied to the first gate insulating layer 91 to form the source-side face-treated portion 91ps and the drain-side face-treated portion 91pd, thereby making it possible to perform an electroless plating process later.

(Second Step in Embodiment 9: Form First Source and Drain Electrode Layers)

As illustrated in FIG. 18(b), the first source electrode layer 94a of the source electrode 94 and the first drain electrode layer 95a of the drain electrode 95 are formed (second step in Embodiment 9, step (e3)).

In the second step of Embodiment 9, the first source electrode layer 94a is formed covering the surface of the source-side face-treated portion 91ps using a well-known electroless plating technique. Using the same method, the first drain electrode layer 95a is formed covering the surface of the drain-side face-treated portion 91pd.

The first source electrode layer 94a and the first drain electrode layer 95a function as adhesion layers in the source electrode 94 and the drain electrode 95, respectively. Here, Ni is selected as the material for the first source electrode layer 94a and the first drain electrode layer 95a.

In other words, an Ni-based first plating solution 96a is applied to the organic TFT 9, thereby causing the first plating solution 96a to adhere to the top surface of the source-side face-treated portion 91ps and the top surface of the drain-side face-treated portion 91pd, where the surface treatment was earlier performed. In this way, the first source electrode layer 94a and the first drain electrode layer 95a are formed.

The source-side face-treated portion 91ps and the drain-side face-treated portion 91pd formed in the first step of Embodiment 9 exhibit strong adhesion with metals. In other words, the source-side face-treated portion 91ps and the drain-side face-treated portion 91pd can function as adhesion layers instead of the first source electrode layer 94a and the first drain electrode layer 95a which were formed as adhesion layers.

Therefore, the second step in Embodiment 9 may be omitted, and in the third step, the second source electrode layer 94b and the second drain electrode layer 95b may be formed covering the top surfaces of the source-side face-treated portion 91ps and the drain-side face-treated portion 91pd, respectively, that function as adhesion layers.

(Third Step in Embodiment 9: Form Second Source and Drain Electrode Layers)

As illustrated in FIG. 18(c), the second source electrode layer 94b of the source electrode 94 and the second drain electrode layer 95b of the drain electrode 95 are formed (third step in Embodiment 9, step (f3)).

The third step of Embodiment 9 is equivalent to the second step in Embodiment 8, and the second source electrode layer 94b and the second drain electrode layer 95b are formed using a well-known electroplating technique. Here, Cu is selected as the material for the second source electrode layer 94b and the second drain electrode layer 95b.

In other words, a Cu-based second plating solution 96b is applied to the organic TFT 9, thereby causing the second plating solution 96b to adhere to the top surface of the first source electrode layer 94a and the top surface of the first drain electrode layer 95a. In this way, the second source electrode layer 94b and the second drain electrode layer 95b are formed.

The second source electrode layer 94b and the second drain electrode layer 95b are auxiliary conductive layers of the source electrode 94 and the drain electrode 95 and are formed in order to reduce the contact resistance of the respective electrodes.

(Fourth Step in Embodiment 9: Form Third Source and Drain Electrode Layers)

As illustrated in FIG. 18(d), the third source electrode layer 94c of the source electrode 94 and the third drain electrode layer 95c of the drain electrode 95 are formed (fourth step in Embodiment 9, step (g3)).

The fourth step of Embodiment 9 is equivalent to third step in Embodiment 8, and the third source electrode layer 94c and the third drain electrode layer 95c are formed using a well-known electroplating technique. Here, Au is selected as the material for the third source electrode layer 94c and the third drain electrode layer 95c.

In other words, an Au-based third plating solution 96c is applied to the organic TFT 9, thereby causing the third plating solution 96c to adhere to the top surface of the second source electrode layer 94b and the top surface of the second drain electrode layer 95b. In this way, the third source electrode layer 94c and the third drain electrode layer 95c are formed.

The third source electrode layer 94c and the third drain electrode layer 95c are the primary conductive layers of the source electrode 94 and the drain electrode 95 and are formed in order to make good contact with the organic semiconductor layer 16.

(Fifth Step in Embodiment 9: Form Organic Semiconductor Layer)

As illustrated in FIG. 18(e), the organic semiconductor layer 16 is formed on top of the second gate insulating layer 92, the source electrode 94, and the drain electrode 95 such that the organic semiconductor layer 16 completely covers the surface of the second gate insulating layer 92 and partially covers the surfaces of the source electrode 94 and the drain electrode 95 (fifth step in Embodiment 9).

The fifth step in Embodiment 9 corresponds to the fourth step in Embodiment 8, and like in that fourth step in Embodiment 8 (that is, like in the seventh step (step(g1)) in Embodiment 1), the organic semiconductor layer 16 is formed to complete the organic TFT 9 of the present embodiment.

(Effects of Organic TFT 9)

In the organic TFT 9 of the present embodiment, the source electrode 94 that includes the first source electrode layer 94a, the second source electrode layer 94b, and the third source electrode layer 94c as well the drain electrode 95 that includes the first drain electrode layer 95a, the second drain electrode layer 95b, and the third drain electrode layer 95c are both formed using a plating method.

In the organic TFT 8 of Embodiment 8, the second source electrode layer 84b and the third source electrode layer 84c as well the second drain electrode layer 85b and the third drain electrode layer 95c were also formed using a plating method. However, in the organic TFT 8 of Embodiment 8, the first source electrode layer 84a and the first drain electrode layer 85a that function as adhesion layers are formed using photolithography.

The organic TFT 9 of the present embodiment differs from the organic TFT 8 of Embodiment 8 in that the first source electrode layer 94a and the first drain electrode layer 95a that function as adhesion layers are also formed using a plating method.

Therefore, in the organic TFT 9 of the present embodiment, the first source electrode layer 94a and the first drain electrode layer 95a that function as adhesion layers are not formed using a photolithography process that requires a large number of steps. As a result, the required manufacturing time and costs can be further reduced in comparison with the organic TFT 8 of Embodiment 8.

(Modification Example)

In the organic TFT 9, the source electrode 94 and the drain electrode 95 may also be configured to not include the first source electrode layer 94a and the first drain electrode layer 95a that function as adhesion layers and such that the second source electrode layer 94b and the second drain electrode layer 95b that function as auxiliary conductive layers have a multi-layer structure.

In this case, the second gate insulating layer 92 may be formed thicker than the total thickness of the layers of the source electrode 94 other than the uppermost layer (that is, other than the third source electrode layer 94c) and the total thickness of the layers of the drain electrode 95 other than the uppermost layer (that is, other than the third drain electrode layer 95c) but thinner than the overall source electrode 94 and the overall drain electrode 95.

Furthermore, in the organic TFT 9, the uppermost layers of the source electrode 94 and the drain electrode 95 (that is, the third source electrode layer 94c and the third drain electrode layer 95c) are connected via the openings 19 formed in the second gate insulating layer to the layers of the source electrode 94 and the drain electrode 95 other than those uppermost layers.

In the modification example described above that does not include the first source electrode layer 94a and the first drain electrode layer 95a that function as adhesion layers and in which the second source electrode layer 94b and the second drain electrode layer 95b that function as auxiliary conductive layers have a multi-layer structure, the same configuration can be used for the openings to achieve the same effect.

(Summary)

A semiconductor element according to aspect 1 of the present invention includes: a gate electrode (13); a first gate insulating layer (11) covering the gate electrode; a source electrode (14) and a drain electrode (15) formed with a gap therebetween on top of the first gate insulating layer such that, in a plan view, the source electrode and the drain electrode are disposed on either side of the gate electrode and both partially overlap, through the first gate insulating layer, with the gate electrode; a second gate insulating layer (12) formed on top of the first gate insulating layer in at least a region sandwiched between the source electrode and the drain electrode; and a semiconductor layer (16) formed between and on top of the source electrode and the drain electrode and overlapping, through the first gate insulating layer, the second gate insulating layer, the source electrode, and the drain electrode, with the gate electrode, wherein the source electrode and the drain electrode each include a plurality of layers, wherein uppermost layers of the source electrode and the drain electrode are formed using a material that has a smaller difference in work function relative to a material used for the semiconductor layer than does a material used for layers of the source electrode and the drain electrode other than the uppermost layers, and wherein top and side faces of the source electrode and the drain electrode contact the semiconductor layer directly, and the layers of the source electrode and the drain electrode other than the uppermost layers are separated from the semiconductor layer by at least one of the second gate insulating layer and the uppermost layers of the source electrode and the drain electrode.

In the bottom-gate, bottom-contact semiconductor element described above, current flows between the source electrode and the drain electrode along the interface between the semiconductor layer and the gate insulating layer.

Therefore, when the source electrode and the drain electrode each include a plurality of layers, if any of the layers of the source electrode and the drain electrode that contact the interface between the semiconductor layer and the gate insulating layer do not make good contact with the semiconductor layer, contact resistance increases and the performance of the semiconductor element decreases.

The contact resistance of the source electrode and the drain electrode increases as the difference in work function of the material used for the source electrode and drain electrode relative to the material used for the semiconductor layer increases. Therefore, it is preferable that the difference in work function between the material used for the source electrode and the drain electrode and the material used for the semiconductor layer be as small as possible. One typical example of such a material is gold. However, gold is an expensive material.

Furthermore, in order to improve adhesion between the source electrode and the drain electrode and the gate insulating layer, it is preferable that the source electrode and the drain electrode each include a layer that exhibits strong adhesion (high wettability) with the gate electrode and functions as an adhesion layer with the gate insulating layer. However, such adhesion layers cannot make good contact with the semiconductor layer. Therefore, it is preferable that, in addition to the layers for making good contact with the semiconductor layer, the source electrode and the drain electrode each include a layer that exhibits strong adhesion (high wettability) with the gate electrode and functions as an adhesion layer with the gate insulating layer.

In the semiconductor element described above, the second gate insulating film functions as part of the gate insulating film. Furthermore, in the region sandwiched between the source electrode and the drain electrode, the layers of the source electrode and the drain electrode other than the uppermost layers are separated from the semiconductor layer by at least one of the second gate insulating layer and the uppermost layers of the source electrode and the drain electrode.

As a result, the semiconductor layer does not directly contact the layers of the source electrode and the drain electrode other than the uppermost layers. Therefore, in the configuration described above, electrical contact between the layers of the source electrode and the drain electrode other than the uppermost layers (which have a work function very different from that of the semiconductor layer) and the semiconductor layer is reduced.

Meanwhile, the semiconductor layer does directly contact the uppermost layers of the source electrode and the drain electrode. Therefore, the uppermost layers of the source electrode and the drain electrode (which have a work function similar to that of the semiconductor layer) can make good electrical contact with the semiconductor layer.

Moreover, the semiconductor layer does not directly contact the layers of the source electrode and the drain electrode other than the uppermost layers. This makes it possible to reduce electrical contact between the layers of the source electrode and the drain electrode other than the uppermost layers (which have a work function more different from that of the semiconductor layer) and the semiconductor layer.

Therefore, the configuration described above makes it possible to reduce the performance decreases that typically occur when using multilayer source and drain electrodes in a bottom-gate semiconductor element.

Furthermore, in a semiconductor element according to aspect 2 of the present invention, the semiconductor element according to aspect 1 may be configured such that the source electrode and the drain electrode each include layers (such as the first source electrode layer 14a and the first drain electrode layer 15a) that function as adhesion layers with the first gate insulating layer, and such that the second gate insulating layer is formed thicker than at least the adhesion layers (which have a thickness of d1, for example) but thinner than the overall source electrode and the overall drain electrode (which have a thickness of d1+d2, for example).

In this configuration, in the region sandwiched between the source electrode and the drain electrode, at least portions of the side faces of the uppermost layers of the source electrode and the drain electrode are not covered by the second gate insulating layer, and the side faces of the adhesion layers are covered by the second gate insulating layer such that those adhesion layers do not directly contact the semiconductor layer.

Therefore, the second gate insulating layer makes it possible to reduce electrical contact between the semiconductor layer and the adhesion layers of the source electrode and the drain electrode and also makes it possible to achieve good electrical contact between the semiconductor layer and the uppermost layers of the source electrode and the drain electrode.

This, in turn, makes it possible to reduce the performance decreases that typically occur in a bottom-gate semiconductor element that includes adhesion layers.

Furthermore, in a semiconductor element according to aspect 3 of the present invention, the semiconductor element according to the aspect 1 or 2 may be configured such that the second gate insulating layer is formed thicker than the total thickness of the layers of the source electrode other than the uppermost layer and the total thickness of the layers of the drain electrode other than the uppermost layer but thinner than the overall source electrode and the overall drain electrode.

In this configuration, in the region sandwiched between the source electrode and the drain electrode, the side faces of the uppermost layers of the source electrode and the drain electrode are not covered by the second gate insulating layer, and the side faces of the layers of the source electrode and the drain electrode other than the uppermost layers are covered by the second gate insulating layer such that those layers do not directly contact the semiconductor layer.

Therefore, the second gate insulating layer makes it possible to reduce electrical contact between the semiconductor layer and the layers of the source electrode and the drain electrode other than the uppermost layers and also makes it possible to achieve good electrical contact between the semiconductor layer and the uppermost layers of the source electrode and the drain electrode.

Moreover, in a semiconductor element according to aspect 4 of the present invention, the semiconductor element according to aspect 1 may be configured such that the source electrode and the gate electrode are each two-layer electrodes that each include a layer that functions as an adhesion layer with the first gate insulating layer (such as the first source electrode layer 14a and the first drain electrode layer 15a) and an uppermost layer (such as the second source electrode layer 14b and the second drain electrode layer 15b), such that the second gate insulating layer includes a source-side second gate insulating layer (52a) that covers the side face of the source electrode adhesion layer in the region sandwiched between the source electrode and the drain electrode (such as the first source electrode layer side face 14aS) and a drain-side second gate insulating layer (52b) that covers the side face of the drain electrode adhesion layer in the region sandwiched between the source electrode and the drain electrode (such as the first drain electrode layer side face 15aS), and such that the source-side second gate insulating layer and the drain-side second gate insulating layer are formed with a gap therebetween.

In the configuration described above, the source-side second gate insulating layer and the drain-side second gate insulating layer make it possible to reduce electrical contact between the semiconductor layer and the adhesion layers and also make it possible to achieve good electrical contact between the semiconductor layer and the uppermost layers of the source electrode and the drain electrode.

Moreover, in the configuration described above, in the area where the source-side second gate insulating layer and the drain-side second gate insulating layer do not contact one another (such as the center portion of the region between the source electrode and the drain electrode), only the first gate insulating layer (which has a uniform thickness) is present as part of the gate insulating layer. This makes it possible to reduce distribution and variation in the performance of the semiconductor element in comparison with when the second gate insulating layer is formed in the entire region sandwiched between the source electrode and the drain electrode.

Furthermore, in a semiconductor element according to aspect 5 of the present invention, the semiconductor element according to aspect 1 or 2 may be configured such that the second gate insulating layer completely covers the surfaces of the layers of the source electrode and the drain electrode other than the uppermost layers that do not contact the uppermost layers of the source electrode and the drain electrode.

In the configuration described above, even when the uppermost layers of the source electrode and the drain electrode partially contact the layers of the source electrode and the drain electrode other than the uppermost layers via connecting portions (such as the second source electrode layer 14b and the second drain electrode layer 15b formed in openings (19) of the second gate insulating layer), the second gate insulating layer completely covers the surfaces of the layers of the source electrode and the drain electrode other than the uppermost layers that do not contact the uppermost layers of the source electrode and the drain electrode. Moreover, in this configuration, the second gate insulating layer also covers the side faces of the layers of the source electrode and the drain electrode other than the uppermost layers opposite to the side faces in the region sandwiched between the source electrode and the drain electrode.

Therefore, in this configuration the second gate insulating layer makes it possible to reduce electrical contact between the semiconductor layer and the layers of the source electrode and the drain electrode other than the uppermost layers and also makes it possible to achieve good electrical contact between the semiconductor layer and the uppermost layers of the source electrode and the drain electrode.

Furthermore, the configuration described above can easily be achieved even without using an inkjet method, by using a process such as photolithography.

Furthermore, in a semiconductor element according to aspect 6 of the present invention, the semiconductor element according to aspect 5 may be configured such that the second gate insulating layer partially covers the layers of the source electrode and the drain electrode other than the uppermost layers and includes openings (19) that contact those layers of the source electrode and the drain electrode other than the uppermost layers, and such that the uppermost layers of the source electrode and the drain electrode are connected via the openings formed in the second gate insulating layer to the layers of the source electrode and the drain electrode other than the uppermost layers (such as the first source electrode layer 14a and the first drain electrode layer 15a).

In this configuration, the second gate insulating layer can be patterned using photolithography. This makes it possible to accurately control the film thickness and shape of the second gate insulating film as well as to reduce distribution and variation in the performance of the semiconductor element.

Moreover, in the configuration described above, forming openings in the second gate insulating layer makes it possible to easily form the source electrode and the drain electrode to include a plurality of layers.

Furthermore, in a semiconductor element according to aspect 7 of the present invention, the semiconductor element according to aspect 6 may be configured such that the edges of the uppermost layers of the source electrode and the drain electrode (such as the second source electrode layer 14b and the second drain electrode layer 15b) facing one another extend more deeply into the region sandwiched between the source electrode and the drain electrode than do the edges of the layers of the source electrode and the drain electrode other than the uppermost layers (such as the first source electrode layer 14a and the first drain electrode layer 15a) facing one another.

Therefore, even if a misalignment occurs during the photolithography process for forming the layers of the source electrode and the drain electrode other than the uppermost layers, a channel is still formed in the semiconductor layer between the edges of the uppermost layers of the source electrode and the drain electrode facing one another, which extend more deeply into the region sandwiched between the source electrode and the drain electrode. Moreover, a gate voltage for controlling the channel is applied from the gate electrode to the same region.

Therefore, even if a misalignment occurs during the photolithography processes for forming the uppermost layers of the source electrode and the drain electrode and the layers other than the uppermost layers, the controllability of the channel in the semiconductor layer can still be improved, and decreases in the performance of the semiconductor element can still be reduced.

Furthermore, in a semiconductor element according to aspect 8 of the present invention, the semiconductor element according to aspect 5 may be configured such that the second gate insulating layer is formed thinner than the total thickness of the layers of the source electrode and the drain electrode other than the uppermost layers and includes openings, such that the layers of the source electrode and the drain electrode other than the uppermost layers that are adjacent to those uppermost layers are formed partially protruding from the openings in the second gate insulating layer, and such that the uppermost layers of the source electrode and the drain electrode cover the portions of the layers of the source electrode and the drain electrode other than the uppermost layers that are adjacent to those uppermost layers and protrude from the second gate insulating layer.

In this configuration, the second gate insulating layer can be patterned using photolithography. This makes it possible to accurately control the film thickness and shape of the second gate insulating film as well as to reduce distribution and variation in the performance of the semiconductor element.

Moreover, in the configuration described above, the layers of the source electrode and the drain electrode other than the uppermost layers can easily be separated from the semiconductor layer by the second gate insulating layer and the uppermost layers of the source electrode and the drain electrode simply by forming the uppermost layers of the source electrode and the drain electrode to cover the portions of the layers of the source electrode and the drain electrode that are adjacent to the uppermost layers and protrude from the second gate insulating layer. In addition, the configuration described above can easily be formed with just the uppermost layers of the source electrode and the drain electrode being exposed from the second gate insulating layer.

Furthermore, in a semiconductor element according to aspect 9 of the present invention, the semiconductor element according to aspect 8 may be configured such that of the layers of the source electrode and the drain electrode other than the uppermost layers, at least the layers adjacent to the uppermost layers of the source electrode and the drain electrode are electroless plating layers.

In this configuration of the semiconductor element, at least the layers adjacent to the uppermost layers of the source electrode and the drain electrode are formed using electroless plating, thereby making it possible to simplify the method for producing the source electrode and the drain electrode.

Furthermore, in a semiconductor element according to aspect 10 of the present invention, the semiconductor element according to aspect 9 may be configured such that an electroless plating catalyst selectively adheres to the contact surfaces between the first gate insulating layer and the source electrode and drain electrode.

For example, the first gate insulating layer may be made from a polyimide, and holes in which palladium (an electroless plating catalyst) adheres may be selectively formed in the contact surfaces between the first gate insulating layer and the source electrode and drain electrode.

In this configuration, the layers of the source electrode and the drain electrode other than the uppermost layers can be formed in the openings using only electroless plating. This makes it possible to reduce the costs associated with manufacturing the semiconductor device.

Moreover, in the configuration described above, the contact surfaces between the first gate insulating layer and the source electrode and drain electrode function as adhesion layers with the source electrode and the drain electrode. This improves adhesion between the first gate insulating layer and the source electrode and drain electrode, and therefore the source electrode and drain electrode do not necessarily have to include dedicated layers that function as adhesion layers with the first gate insulating layer.

Furthermore, in a semiconductor element according to aspect 11 of the present invention, the semiconductor element according to any one of aspect 5 or aspects 8 to 10 may be configured such that the source electrode and the gate electrode each include three layers, and such that the intermediate layers of the source electrode and the drain electrode (that is, the layers adjacent to the uppermost layers of the source electrode and the drain electrode) are formed using a material that has a smaller difference in work function relative to the material used for the semiconductor layer than does the material used for the lowermost layers of the source electrode and the drain electrode as well as a larger difference in work function relative to the material used for the semiconductor layer than does the material used for the uppermost layers of the source electrode and the drain electrode.

The configuration described above makes it possible to reduce decreases in performance in the semiconductor element even when using source and drain electrodes that each include three layers.

Typically, an extremely expensive metal such as gold is used for the uppermost layers, and therefore it is preferable that the amount of that material used be reduced. The configuration described above makes it possible to reduce the amount of material used for the uppermost layers, and the intermediate layers make it possible to reduce the contact resistance of the source electrode and the drain electrode.

Furthermore, in a semiconductor element according to aspect 12 of the present invention, the semiconductor element according to any one of aspects 1 to 11 may be configured such that the permittivity ε₂ of the second gate insulating layer is less than the permittivity ε₁ of the first gate insulating layer.

This configuration makes it possible to improve the performance of the semiconductor element. Moreover, making the permittivity of the first gate insulating layer greater than the permittivity of the second gate insulating layer makes it possible to increase the film thickness at which a given capacitance is achieved in comparison with a configuration in which the permittivity of the first gate insulating layer is less than the permittivity of the second gate insulating layer. As a result, leakage current can be reduced and the breakdown voltage of the semiconductor element can be improved.

Furthermore, in a semiconductor element according to aspect 13 of the present invention, the semiconductor element according to any one of aspects 1 to 12 may be configured such that the first gate insulating layer and the second gate insulating layer have different surface energies.

For example, setting the surface energy of the second gate insulating layer to a value higher than the surface energy of the first gate insulating layer makes it possible to improve precision while manufacturing the semiconductor element. Meanwhile, setting the surface energy of the second gate insulating layer to a value lower than the surface energy of the first gate insulating layer makes it possible to improve the performance of the semiconductor element.

In a semiconductor element according to aspect 14 of the present invention, the semiconductor element according to aspect 13 may be configured such that the surface energy ES2 of the second gate insulating layer is greater than the surface energy ES1 of the first gate insulating layer.

As described above, this configuration makes it possible to improve precision while manufacturing the semiconductor element.

In a semiconductor element according to aspect 15 of the present invention, the semiconductor element according to aspect 13 may be configured such that the surface energy of the second gate insulating layer is less than the surface energy of the first gate insulating layer.

As described above, this configuration makes it possible to improve the performance of the semiconductor element.

Furthermore, in a semiconductor element according to aspect 16 of the present invention, the semiconductor element according to any one of aspects 1 to 15 may be configured such that the semiconductor layer is an organic semiconductor layer.

This configuration is particularly well-suited to cases in which an organic semiconductor is used as the semiconductor material.

A method of manufacturing a semiconductor element according to aspect 17 of the present invention includes: forming a first gate insulating layer covering a gate electrode; forming a source electrode and a drain electrode with a gap therebetween on the first gate insulating layer such that, in a plan view, the source electrode and the drain electrode are disposed on respective sides of the gate electrode and both partially overlap the gate electrode through the first gate insulating layer; forming a second gate insulating layer on the first gate insulating layer in at least a region between the source electrode and the drain electrode; and forming a semiconductor layer between and on top of the source electrode and the drain electrode, the semiconductor layer overlapping the gate electrode through the first gate insulating layer, the second gate insulating layer, the source electrode, and the drain electrode, wherein, in the step of forming the source electrode and the drain electrode, the source electrode and the drain electrode are each formed of a plurality of layers, and respective uppermost layers of the source electrode and the drain electrode are formed of a material that has a smaller difference in work function relative to a material used for the semiconductor layer as compared to a material used for layers respectively constituting the source electrode and the drain electrode other than the uppermost layers, and wherein, in the step of forming the second gate insulating layer, the second gate insulating layer is formed such that, in the region between the source electrode and the drain electrode on the first gate insulating layer, a thickness of the second gate insulating layer is greater than respective total thicknesses of the layer of the source electrode other than the uppermost layer and a total thickness of the layer of the drain electrode other than the uppermost layer but less than a total thickness of the source electrode and a total thickness of the drain electrode.

The method described above makes it possible to reduce electrical contact between the semiconductor layer and the layers of the source electrode and the drain electrode other than the uppermost layers and also makes it possible to manufacture a semiconductor element which exhibits good electrical contact between the semiconductor layer and the uppermost layers of the source electrode and the drain electrode.

A method of manufacturing a semiconductor element according to aspect 18 of the present invention includes: forming a first gate insulating layer covering a gate electrode; forming a source electrode and a drain electrode with a gap therebetween on the first gate insulating layer such that, in a plan view, the source electrode and the drain electrode are disposed on respective sides of the gate electrode and both partially overlap the gate electrode through the first gate insulating layer, and such that the source electrode and the drain electrode each include two layers; forming a second gate insulating layer on the first gate insulating layer in at least a region between the source electrode and the drain electrode; and forming a semiconductor layer between and on top of the source electrode and the drain electrode, the semiconductor layer overlapping the gate electrode through the first gate insulating layer, the second gate insulating layer, the source electrode, and the drain electrode, wherein the step of forming the source electrode and the drain electrode includes: forming, on the first gate insulating layer, a first source electrode layer and a first drain electrode layer that function as adhesion layers with the first gate insulating layer; and forming, respectively on the first source electrode layer and the first drain electrode layer, a second source electrode layer and a second drain electrode layer made of a material that has a smaller difference in work function relative to a material used for the semiconductor layer as compared to a material used for the first source electrode layer and the first drain electrode layer, wherein the step of forming the second gate insulating layer includes: forming, in the region between the source electrode and the drain electrode, a source-side second gate insulating layer that covers a side face of the first source electrode layer, and forming, in the region between the source electrode and the drain electrode, a drain-side second gate insulating layer covering a side face of the first drain electrode layer, wherein, in the steps of forming the source-side second gate insulating layer and the drain-side second gate insulating layer, the source-side second gate insulating layer and the drain-side second gate insulating layer are formed with a gap therebetween; at least a portion of a side face of the second source electrode layer is exposed; and at least a portion of a side face of the second drain electrode layer is exposed.

The method described above makes it possible to reduce electrical contact between the semiconductor layer and the first source electrode layer and first drain electrode layer and also makes it possible to manufacture a semiconductor element which exhibits good electrical contact between the semiconductor layer and the second source electrode layer and second drain electrode layer.

Moreover, the method described above makes it possible to manufacture a semiconductor element in which, in the area where the source-side second gate insulating layer and the drain-side second gate insulating layer do not contact one another (such as the center portion of the region between the source electrode and the drain electrode), only the first gate insulating layer (which has a uniform thickness) is present as part of the gate insulating layer. This makes it possible to provide a semiconductor element which exhibits reduced distribution and variation in performance in comparison with when the second gate insulating layer is formed in the entire region sandwiched between the source electrode and the drain electrode.

In a method for manufacturing a semiconductor element according to aspect 19 of the present invention, the method according to aspect 17 or 18 may be configured such that in the step of forming the second gate insulating layer, the second gate insulating layer is formed using an inkjet method.

The method described above makes it possible to form the second gate insulating layer only in the necessary areas.

A method of manufacturing a semiconductor element according to aspect 20 of the present invention includes: forming a first gate insulating layer covering a gate electrode; forming a first source electrode layer and a first drain electrode layer with a gap therebetween on the first gate insulating layer such that, in a plan view, the first source electrode layer and the first drain electrode layer are disposed on respective sides of the gate electrode and both partially overlap the gate electrode through the first gate insulating layer; forming, on the first gate insulating layer, on the first source electrode layer, and on the first drain electrode layer, a second gate insulating layer patterned to include openings that respectively expose at least portions of respective top surfaces of the first source electrode layer and the first drain electrode layer; forming, on the second gate insulating layer, a second source electrode layer that is connected to the first source electrode layer via the openings that respectively exposes the first source electrode layer and that is patterned such that, in a plan view, formed with a gap therebetween on either side of the gate electrode, the second source electrode layer partially overlaps the gate electrode through the first gate insulating layer and the first source electrode layer, and forming, on the second gate insulating layer, a second drain electrode layer that is connected to the first drain electrode layer via the openings that respectively expose the first drain electrode layer and that is patterned such that, in a plan view, formed with a gap therebetween on either side of the gate electrode, the second drain electrode layer partially overlaps the gate electrode through the first gate insulating layer and the first drain electrode layer; and forming a semiconductor layer between and on top of the second source electrode layer and the second drain electrode layer, the semiconductor layer overlapping the gate electrode through the first gate insulating layer, the second gate insulating layer, the first source electrode layer, the second source electrode layer, the first drain electrode layer, and the second drain electrode layer, wherein, in the step of forming the second source electrode layer and the second drain electrode layer, the second source electrode layer and the second drain electrode layer are formed of a material that has a smaller difference in work function relative to a material used for the semiconductor layer as compared to a material used for the first source electrode layer and the first drain electrode layer.

The method described above makes it possible to reduce electrical contact between the semiconductor layer and the first source electrode layer and first drain electrode layer and also makes it possible to manufacture a semiconductor element which exhibits good electrical contact between the semiconductor layer and the second source electrode layer and second drain electrode layer.

Moreover, the method described above makes it possible to pattern the second gate insulating layer using photolithography. This makes it possible to accurately control the film thickness and shape of the second gate insulating film as well as to reduce distribution and variation in the performance of the resulting semiconductor element.

Furthermore, in a method for manufacturing a semiconductor element according to aspect 21 of the present invention, the method according to aspect 20 may be configured such that in the step of forming the second source electrode layer and the second drain electrode layer, the second source electrode layer and the second drain electrode layer are formed such that the edges of the second source electrode layer and the second drain electrode layer facing one another extend more deeply into the region sandwiched between the source electrode that includes the first source electrode layer and the second source electrode layer and the drain electrode that includes the first drain electrode layer and the second drain electrode layer than do the edges of the first source electrode layer and the first drain electrode layer facing one another.

In the method described above, even if a misalignment occurs during the photolithography process for forming the layers of the source electrode and the drain electrode other than the uppermost layers, a channel is still formed in the semiconductor layer between the edges of the uppermost layers of the source electrode and the drain electrode facing one another, which extend more deeply into the region sandwiched between the source electrode and the drain electrode. Moreover, a gate voltage for controlling the channel is applied from the gate electrode to the same region.

Therefore, the method described above makes it possible to provide a semiconductor element in which the controllability of the channel in the semiconductor layer can be improved and decreases in performance can be reduced even if a misalignment occurs during the photolithography processes for forming the uppermost layers of the source electrode and the drain electrode and the layers other than the uppermost layers.

A method of manufacturing a semiconductor element according to aspect 22 of the present invention includes: forming a first gate insulating layer covering a gate electrode; forming, on the first gate insulating layer, a second gate insulating layer patterned to include openings that expose the first gate insulating layer in regions that, in a plan view, are disposed with a gap therebetween on respective sides of the gate electrode and partially overlap the gate electrode through the first gate insulating layer; forming, by electroless plating, plating layers, respectively, in the openings, as respective portions of a source electrode and a drain electrode such that portions of the plating layers protrude out from the openings; forming, on the second gate insulating layer, surface plating layers that function as respective uppermost layers of the source electrode and the drain electrode, that respectively cover the portions of the plating layers formed in the step of forming the plating layers and protruding from the openings, the second plating layers being disposed with a gap therebetween on respective sides of the gate electrode and both partially overlapping the gate electrode through the first gate insulating layer in a plan view; and forming a semiconductor layer between and on top of the source electrode and the drain electrode, the semiconductor layer overlapping the gate electrode through the first gate insulating layer, the second gate insulating layer, the source electrode, and the drain electrode, wherein, in the step of forming the surface plating layers, the surface plating layers are formed of a material that has a smaller difference in work function relative to a material used for the semiconductor layer as compared to a material used for the respective plating layers formed in the step of forming the plating layers.

The method described above makes it possible to reduce electrical contact between the semiconductor layer and the layers of the source electrode and the drain electrode other than the uppermost layers and also makes it possible to manufacture a semiconductor element which exhibits good electrical contact between the semiconductor layer and the uppermost layers of the source electrode and the drain electrode.

Moreover, in the method described above, the plating layers inside the openings (such as the first source electrode layer 94a and the first drain electrode layer 95a) as well as the surface plating layers used as parts of the source electrode and the drain electrode are formed using an electroless plating method, thereby making it possible to simplify the process for producing the source electrode and the drain electrode and also making it possible to reduce the costs associated with manufacturing the semiconductor element.

Furthermore, in a method for manufacturing a semiconductor element according to aspect 23 of the present invention, the method according to aspect 22 may be configured to further include, before the step of forming the second gate insulating layer, forming, on top of the first gate insulating layer, layers that function as adhesion layers with the first gate insulating layer, that are used as parts of the source electrode and the drain electrode, and that, in a plan view, are disposed with a gap therebetween on either side of the gate electrode and both partially overlap, through the first gate insulating layer, with the gate electrode, wherein in the step of forming the second gate insulating layer, the second gate insulating layer is patterned such that the openings formed therein expose portions of the top surfaces of the adhesion layers, wherein in the step of forming the plating layers in the openings, the plating layers are formed on top of the adhesion layers exposed by the openings, and wherein in the step of forming the adhesion layers, the adhesion layers are formed using a material that has a greater difference in work function relative to the material used for the semiconductor layer than does the material used for the plating layers in the openings.

The method described above makes it possible to manufacture a semiconductor element in which the source electrode and the drain electrode each include three layers and in which decreases in performance are reduced.

Typically, an extremely expensive metal such as gold is used for the uppermost layers, and therefore it is preferable that the amount of that material used be reduced. The configuration described above makes it possible to reduce the amount of material used for the uppermost layers, and the intermediate layers make it possible to reduce the contact resistance of the source electrode and the drain electrode.

In a method for manufacturing a semiconductor element according to aspect 24 of the present invention, the method according to aspect 22 may be configured to include adhering an electroless plating catalyst to the surfaces of the first gate insulating layer inside the openings before the step of forming the plating layers inside the openings.

This method makes it possible to form the intra-opening plating layers and the surface plating layers inside the openings using only an electroless plating process. This, in turn, makes it possible to reduce the costs associated with manufacturing the semiconductor device.

Moreover, in the method described above, the contact surfaces between the first gate insulating layer and the source electrode and drain electrode function as adhesion layers with the source electrode and the drain electrode. This improves adhesion between the first gate insulating layer and the source electrode and drain electrode, and therefore the source electrode and drain electrode do not necessarily have to include dedicated layers that function as adhesion layers with the first gate insulating layer.

In a method for manufacturing a semiconductor element according to aspect 25 of the present invention, it is preferable that in the method according to aspect 24, the step of forming the plating layers inside the opening include forming, inside the openings and using electroless plating, first plating layers (such as the first source electrode layer 94a and the first drain electrode layer 95a) that function as adhesion layers with the first gate insulating layer and are thinner than the second gate insulating layer, and forming, on top of the first plating layers and using electroless plating, second plating layers (such as the second source electrode layer 94b and the second drain electrode layer 95b) using a material that has a greater difference in work function relative to the material used for the semiconductor layer than does the material used for the first plating layers and such that portions of the second plating layers protrude out of the openings.

This method for manufacturing a semiconductor element makes it possible to manufacture a semiconductor element according to one aspect of the present invention.

The method described above makes it possible to manufacture a semiconductor element in which the source electrode and the drain electrode each include three layers, in which decreases in performance are reduced, and in which the source electrode and the drain electrode that each include three layers can be formed using only electroless plating.

Typically, an extremely expensive metal such as gold is used for the uppermost layers, and therefore it is preferable that the amount of that material used be reduced. The method described above makes it possible to reduce the amount of material used for the uppermost layers, and the intermediate layers make it possible to reduce the contact resistance of the source electrode and the drain electrode.

In a method for manufacturing a semiconductor element according to aspect 26 of the present invention, the method according to any one of aspects 17 to 25 may be configured such that in the step of forming the semiconductor layer, the semiconductor layer is formed using an inkjet method.

Furthermore, in a method for manufacturing a semiconductor element according to aspect 27 of the present invention, the method according to any one of aspects 17 to 25 may be configured such that in the step of forming the semiconductor layer, the semiconductor layer is formed using a spin coating method.

In a method for manufacturing a semiconductor element according to aspect 28 of the present invention, the method according to any one of aspects 17 to 27 may be configured such that in the step of forming the second gate insulating layer, the second gate insulating layer is formed using a material that has a permittivity less than the permittivity of the first gate insulating layer.

This method makes it possible to improve the performance of the resulting semiconductor element. Moreover, making the permittivity of the first gate insulating layer greater than the permittivity of the second gate insulating layer makes it possible to increase the film thickness at which a given capacitance is achieved in comparison with a configuration in which the permittivity of the first gate insulating layer is less than the permittivity of the second gate insulating layer. As a result, leakage current can be reduced and the breakdown voltage of the semiconductor element can be improved.

In a method for manufacturing a semiconductor element according to aspect 29 of the present invention, the method according to aspect 26 may be configured such that in the step of forming the second gate insulating layer, the second gate insulating layer is formed using a material that has a surface energy greater than the surface energy of the first gate insulating layer.

This method makes it possible to improve precision while manufacturing the semiconductor element.

In a method for manufacturing a semiconductor element according to aspect 30 of the present invention, the method according to aspect 27 may be configured such that in the step of forming the second gate insulating layer, the second gate insulating layer is formed using a material that has a surface energy less than the surface energy of the first gate insulating layer.

This method makes it possible to improve the performance of the resulting semiconductor element.

Furthermore, in a method for manufacturing a semiconductor element according to aspect 31 of the present invention, the method according to aspect 26 may be configured to further include, before the step of forming the semiconductor layer, applying a surface treatment to the second gate insulating layer obtained from the step of forming the second gate insulating layer in order to make the surface energy of the second gate insulating layer greater than the surface energy of the first gate insulating layer.

This method for manufacturing a semiconductor element makes it possible to manufacture a semiconductor element according to one aspect of the present invention.

This method also makes it possible to improve precision while manufacturing the semiconductor element.

Furthermore, in a method for manufacturing a semiconductor element according to aspect 32 of the present invention, the method according to aspect 27 may be configured to further include, between the step of forming the first gate insulating layer and the second gate insulating layer, applying a surface treatment to the first gate insulating layer obtained from the step of forming the first gate insulating layer in order to make the surface energy of the first gate insulating layer greater than the surface energy of the second gate insulating layer.

This method makes it possible to improve the performance of the resulting semiconductor element.

In a method for manufacturing a semiconductor element according to aspect 33 of the present invention, the method according to aspect 31 or 32 may be configured such that the surface treatment is irradiation with UV light.

In a method for manufacturing a semiconductor element according to aspect 34 of the present invention, the method according to aspect 31 or 32 may be configured such that the surface treatment is application of a monolayer film such as a silane coupling agent.

(Additional Notes)

The present invention is not limited to the embodiments described above, and various modifications can be made without departing from the scope of the claims. Therefore, embodiments obtained by appropriately combining the techniques disclosed in different embodiments are included in the technical scope of the present invention. Furthermore, the techniques disclosed in each embodiment can be combined to achieve new technical features.

The present invention can also be described as follows.

The semiconductor element of the present invention employs an organic semiconductor layer. The source and drain electrodes each include two or more layers. A gate insulating film includes a first insulating film that covers the majority of a substrate and a second insulating film formed at least in a channel region of the transistor. The second insulating film covers the surfaces of the source and drain electrodes other than the surfaces of the uppermost layers (which allow the source electrode and drain electrode to make good contact with the organic semiconductor layer) such that those other surfaces do not contact the organic semiconductor layer.

Moreover, in the semiconductor element of the present invention, the second insulating film is formed thicker than the film thickness of the first source and drain electrode layers (adhesion layers) that contact the first insulating film but thinner than the overall film thickness of the source and drain electrodes.

Furthermore, in the semiconductor element of the present invention, the second insulating film has a smaller permittivity than the first insulating film.

In addition, in the semiconductor element of the present invention, the first insulating film and the second insulating film have different surface energies.

Moreover, in the semiconductor element of the present invention, the first insulating film is formed using a material or a surface treatment that makes it possible to perform electroless plating thereon. The second insulating film is formed using a material or a surface treatment that prevents the second insulating film from undergoing electroless plating. At least the first layers of the source and drain electrodes are formed using an electroless plating process after patterning the second insulating film.

### INDUSTRIAL APPLICABILITY

The present invention can be applied to a semiconductor element and a method for manufacturing a semiconductor element.

Description of Reference Characters

| | |
|---|---|
| 1, 2, 3, 4, 5, 6, 7, 8, 9 | organic TFT (semiconductor element) |
| 10 | substrate |
| 11, 21, 31, 41, 81, 91 | first gate insulating layer |
| 12, 22, 32, 42, 52, 62, 72, 82, 92 | second gate insulating layer |
| 13 | gate electrode |
| 14, 64, 74, 84, 94 | source electrode |
| 14a, 64a, 74a, 84a, 94a | first source electrode layer |
| 14aS, 64aS, 74aS | first source electrode layer side face |
| 14b, 64b, 74b | second source electrode layer |
| 14bS, 64bS, 74bS | second source electrode layer side face |
| 15, 65, 75, 85, 95 | drain electrode |
| 15a, 65a, 75a, 85a, 95a | first drain electrode layer |
| 15aS, 65aS, 75aS | first drain electrode layer side face |
| 15b, 65b, 75b | second drain electrode layer |
| 15bS, 65bS, 75bS | second drain electrode layer side face |
| 16 | organic semiconductor layer (semiconductor layer) |
| 17 | gate electrode layer base material |
| 18 | source/drain electrode layer base material |
| 18a | first source/drain electrode layer base material |
| 18b | second source/drain electrode layer base material |
| 19 | opening |
| 52a | source-side second gate insulating layer |
| 52b | drain-side second gate insulating layer |
| 84b | second source electrode layer (source electrode |
| | intermediate layer) |
| 84c | third source electrode layer (second source |
| | electrode layer) |
| 85b | second drain electrode layer (drain electrode |
| | intermediate layer) |
| 85c | third drain electrode layer (second drain electrode |
| | layer) |
| 94a | first source electrode layer (plating layer, intra- |
| | opening plating layer, first plating layer) |
| 94b | second source electrode layer (second plating layer) |
| 94c | third source electrode layer (surface plating layer) |
| 95a | first drain electrode layer (plating layer, intra- |
| | opening plating layer, first plating layer) |
| 95b | second drain electrode layer (second plating layer) |
| 95c | third drain electrode layer (surface plating layer) |
| 91p | surface-treated portion (hole) |
| d | thickness of second gate insulating layer |
| d1 | thickness of first source electrode layer and first |
| | drain electrode layer |
| d2 | thickness of second source electrode layer and |
| | second drain electrode layer |
| SD1 | distance in horizontal direction between first source |
| | electrode layer side face and first drain electrode layer side face |
| SD2 | distance in horizontal direction between second |
| | source electrode layer side face and second drain electrode layer side face |
| ε₁ | permittivity of first gate insulating layer |
| ε₂ | permittivity of second gate insulating layer |
| ES1 | surface energy of first gate insulating layer |
| ES2 | surface energy of second gate insulating layer |

1. A semiconductor element, comprising:
a substrate;
a gate electrode on the substrate;
a first gate insulating layer disposed on the substrate so as to cover the gate electrode;
a source electrode and a drain electrode formed with a gap therebetween on the first gate insulating layer such that, in a plan view, the source electrode and the drain electrode are disposed on respective sides of the gate electrode and both partially overlap the gate electrode through the first gate insulating layer;
a second gate insulating layer formed on the first gate insulating layer in at least a region between the source electrode and the drain electrode; and
a semiconductor layer formed on the second gate insulating layer and on the source electrode and the drain electrode, said semiconductor layer overlapping the gate electrode through the first gate insulating layer and the second gate insulating layer,
wherein the source electrode and the drain electrode each include a plurality of layers,
wherein, in each of the source electrode and the drain electrode, an uppermost layer is formed of a material that has a smaller difference in work function relative to the semiconductor layer as compared to other layers respectively constituting the source electrode and the drain electrode, and
wherein respective top and side faces of the source electrode and the drain electrode contact the semiconductor layer directly, and said other layers respectively constituting the source electrode and the drain electrode are separated from the semiconductor layer by at least one of the second gate insulating layer and the respective uppermost layers of the source electrode and the drain electrode.

2. A method of manufacturing a semiconductor element, comprising:
forming a gate electrode on a substrate;
forming a first gate insulating layer on the substrate so as to cover the gate electrode;
forming a source electrode and a drain electrode with a gap therebetween on the first gate insulating layer such that, in a plan view, the source electrode and the drain electrode are disposed on respective sides of the gate electrode and both partially overlap the gate electrode through the first gate insulating layer;
forming a second gate insulating layer on the first gate insulating layer in at least a region between the source electrode and the drain electrode; and
forming a semiconductor layer on the second gate insulating layer and on the source electrode and the drain electrode, said semiconductor layer overlapping the gate electrode through the first gate insulating layer and the second gate insulating layer,
wherein, in the step of forming the source electrode and the drain electrode, the source electrode and the drain electrode are each formed of a plurality of layers, and respective uppermost layers of the source electrode and the drain electrode are formed of a material that has a smaller difference in work function relative to the semiconductor layer as compared to other layers respectively constituting the source electrode and the drain electrode, and
wherein, in the step of forming the second gate insulating layer, the second gate insulating layer is formed such that, in the region between the source electrode and the drain electrode on the first gate insulating layer, a thickness of the second gate insulating layer is greater than respective individual thicknesses of the other layers respectively constituting the source electrode and the drain electrode but less than a total thickness of the source electrode and a total thickness of the drain electrode.

3. A method of manufacturing a semiconductor element, comprising:
forming a gate electrode on a substrate;
forming a first gate insulating layer on the substrate so as to cover the gate electrode;
forming a source electrode and a drain electrode with a gap therebetween on the first gate insulating layer such that, in a plan view, the source electrode and the drain electrode are disposed on respective sides of the gate electrode and both partially overlap the gate electrode through the first gate insulating layer, and such that the source electrode and the drain electrode each include two layers;
forming a second gate insulating layer on the first gate insulating layer in at least a region between the source electrode and the drain electrode; and
forming a semiconductor layer on the second gate insulating layer and on the source electrode and the drain electrode, said semiconductor layer overlapping the gate electrode through the first gate insulating layer and the second gate insulating layer,
wherein the step of forming the source electrode and the drain electrode includes:
forming, on the first gate insulating layer, a first source electrode layer and a first drain electrode layer that function as adhesion layers with the first gate insulating layer; and
forming, respectively on the first source electrode layer and the first drain electrode layer, a second source electrode layer and a second drain electrode layer made of a material that has a smaller difference in work function relative to the semiconductor layer as compared to the first source electrode layer and the first drain electrode layer, the first and second source electrodes thereby constituting said source electrode, and the first and second drain electrodes thereby constituting said drain electrode,
wherein the step of forming the second gate insulating layer includes:
forming, in a region between the source electrode and the drain electrode, a source-side second gate insulating layer that covers a side face of the first source electrode layer, and
forming, in a region between the source electrode and the drain electrode, a drain-side second gate insulating layer covering a side face of the first drain electrode layer, the source-side second gate insulating layer and the drain-side second gate insulating layer thereby collectively constituting the second gate insulating layer,
wherein the source-side second gate insulating layer and the drain-side second gate insulating layer are formed with a gap therebetween; at least a portion of a side face of the second source electrode layer is exposed from the source-side second gate insulating layer; and at least a portion of a side face of the second drain electrode layer is exposed from the drain-side second gate insulating layer.

4. A method of manufacturing a semiconductor element, comprising:
forming a gate electrode on a substrate;
forming a first gate insulating layer on the substrate so as to cover the gate electrode;
forming a first source electrode layer and a first drain electrode layer with a gap therebetween on the first gate insulating layer such that, in a plan view, the first source electrode layer and the first drain electrode layer are disposed on respective sides of the gate electrode and both partially overlap the gate electrode through the first gate insulating layer;
forming, on the first gate insulating layer, on the first source electrode layer, and on the first drain electrode layer, a second gate insulating layer patterned to include two openings that respectively expose at least portions of respective top surfaces of the first source electrode layer and the first drain electrode layer;
forming, on the second gate insulating layer, a second source electrode layer that is connected to the first source electrode layer via one of said two openings and that is patterned such that, in a plan view, the second source electrode layer partially overlaps the gate electrode through the first gate insulating layer and the first source electrode layer, and forming, on the second gate insulating layer, a second drain electrode layer that is connected to the first drain electrode layer via another of said two openings such that, in a plan view, the second drain electrode layer partially overlaps the gate electrode through the first gate insulating layer and the first drain electrode layer, the second source electrode and the second drain electrode being separated with a gap therebetween on the respective sides of the gate electrode; and
forming a semiconductor layer on the second gate insulating layer and on the second source electrode layer and the second drain electrode layer, said semiconductor layer overlapping the gate electrode through the first gate insulating layer and the second gate insulating layer,
wherein, in the step of forming the second source electrode layer and the second drain electrode layer, the second source electrode layer and the second drain electrode layer are formed of a material that has a smaller difference in work function relative to the semiconductor layer as compared to the first source electrode layer and the first drain electrode layer.

5. A method of manufacturing a semiconductor element, comprising:
forming a gate electrode on a substrate;
forming a first gate insulating layer on the substrate so as to cover the gate electrode;
forming, on the first gate insulating layer, a second gate insulating layer patterned to include two openings that expose the first gate insulating layer in two regions that, in a plan view, are disposed with a gap therebetween on respective sides of the gate electrode and partially overlap the gate electrode through the first gate insulating layer;
forming, by electroless plating, first plating layers, respectively, in said two openings such that respective top portions of the first plating layers protrude out from the openings;
forming, on the second gate insulating layer, second plating layers that respectively cover the top portions of the first plating layers protruding from the openings, said second plating layers being disposed with a gap therebetween on respective sides of the gate electrode and both partially overlapping the gate electrode through the first gate insulating layer in a plan view, the first and second plating layers at one of the openings together serving as a source electrode and the first and second plating layers at another of the openings together serving as a drain electrode; and
forming a semiconductor layer on the second gate insulating layer and on the source electrode and the drain electrode, said semiconductor layer overlapping the gate electrode through the first gate insulating layer and the second gate insulating layer,
wherein, in the step of forming the second plating layers, the second plating layers are formed of a material that has a smaller difference in work function relative to the semiconductor layer as compared to the respective first plating layers formed in the step of forming the first plating layers.
